(19) United States
(12) Patent Application Publication
(10) Pub. No.: US 2016/0056032 A1
(43) Pub. Date: Feb. 25, 2016

(54) METHODS AND APPARATUSES FOR STABLE DEPOSITION RATE CONTROL IN LOW TEMPERATURE ALD SYSTEMS BY SHOWERHEAD ACTIVE HEATING AND/OR PEDESTAL COOLING

(71) Applicant: Lam Research Corporation, Fremont, CA (US)

(72) Inventors: Chloe Baldasseroni, Portland, CA (US); Adrien LaVoie, Newberg, OR (US); Hu Kang, Tualatin, OR (US); Jun Qian, Tualatin, OR (US); Purushottam Kumar, Hillsboro, OR (US); Andrew Duvall, Portland, CA (US); Cody Barnett, Portland, CA (US); Mohamed Sabri, Beaverton, OR (US); Ramesh Chandrasekharan, Portland, OR (US); Karl F. Leeser, West Linn, OR (US); David C. Smith, Lake Oswego, OR (US); Seshasayee Varadarajan, Lake Oswego, OR (US); Edmund B. Minshall, Sherwood, OR (US)

(21) Appl. No.: 14/466,925

(22) Filed: Aug. 22, 2014

(51) Int. Cl. H01L 21/02; C23C 16/46; C23C 16/52; C23C 16/455; C23C 16/458

(52) U.S. Cl. CPC H01L 21/0228; C23C 16/45544; C23C 16/458; C23C 16/52; C23C 16/45565; C23C 16/463; C23C 16/46

(57) ABSTRACT

Disclosed are methods of depositing films of material on semiconductor substrates. The methods may include flowing a film precursor into a processing chamber through a showerhead substantially maintained at a first temperature, and adsorbing the film precursor onto a substrate held on a substrate holder such that the precursor forms an adsorption-limited layer while the substrate holder is substantially maintained at a second temperature. The first temperature may be at least about 10° C. above the second temperature, or the first temperature may be at or below the second temperature. The methods may further include removing at least some unadsorbed film precursor from the volume surrounding the adsorbed film precursor, and thereafter reacting adsorbed film precursor to form a film layer. Also disclosed herein are apparatuses having a processing chamber, a substrate holder, a showerhead, and one or more controllers for operating the apparatus to employ the foregoing film deposition techniques.

### BACKGROUND

As device and features size continue to shrink in the semiconductor industry, and also as 3D devices structures (e.g., Intel's Tri-Gate transistor architecture) become more prevalent in integrated circuit (IC) design, the capability of depositing thin conformal films (films of material having a uniform thickness relative to the shape of the underlying structure, even if non-planar) will continue to gain importance. Atomic layer deposition (ALD) is a film forming technique which is well-suited to the deposition of conformal films due to the fact that a single cycle of ALD only deposits a single thin layer of material, the thickness being limited by the amount of one or more film precursor reactants which may adsorb onto the substrate surface (i.e., forming an adsorption-limited layer) prior to the film-forming chemical reaction itself. Multiple “ALD cycles” may then be used to build up a film of the desired thickness, and since each layer is thin and conformal, the resulting film substantially conforms to the shape of the underlying devices structure.

There are many challenges associated with ALD processes, however. Often these challenges have to do with the fact that a single cycle of ALD only deposits a thin adsorption-limited layer, and thus many ALD cycles are required to build up a film of appreciable thickness. For this reason, to deposit a film of uniform thickness from wafer-to-wafer via ALD, it is important to minimize any variations in process conditions which might contribute to measurable variations in the deposited film. Accordingly, improved methods and apparatuses are sought which improve the consistency, controllability, and/or repeatability of process conditions over multiple ALD cycles performed on multiple semiconductor substrates.

### SUMMARY

Disclosed herein are methods of depositing a film of material on a semiconductor substrate in a processing chamber. The methods may include flowing a film precursor into a processing chamber through a showerhead while the showerhead is substantially maintained at a first temperature, and adsorbing the film precursor onto a substrate held on a substrate holder in the processing chamber such that the precursor forms an adsorption-limited layer on the substrate while the substrate holder is substantially maintained at a second temperature. The methods may further include removing at least some unadsorbed film precursor from the volume surrounding the adsorbed film precursor, and thereafter reacting adsorbed film precursor to form a film layer on the substrate. In some embodiments, the first temperature may be at least 10° C. above the second temperature.

Also disclosed herein are methods of depositing a film of material on a semiconductor substrate in a processing chamber. The methods may include flowing a film precursor into a processing chamber through a showerhead while the showerhead is substantially maintained at a first temperature, and adsorbing the film precursor onto a substrate held on a substrate holder in the processing chamber such that the precursor forms an adsorption-limited layer on the substrate while the substrate holder is substantially maintained at a second temperature. The methods may further include removing at least some unadsorbed film precursor from the volume surrounding the adsorbed film precursor, and thereafter reacting adsorbed film precursor to form a film layer on the substrate. In some embodiments, the first temperature is at or below the second temperature.

Also disclosed herein are apparatuses for depositing films of material on semiconductor substrates. The apparatuses may include a processing chamber, a substrate holder in the processing chamber, a showerhead for flowing film precursor into the processing chamber, a vacuum source for removing unadsorbed film precursor from the volume surrounding the substrate in the processing chamber, and one or more controller(s). The one or more controller(s) may include machine-readable instructions for operating the showerhead and vacuum source to deposit films of material onto the substrates. The instructions may include instructions for: flowing a film precursor into the processing chamber through the showerhead while substantially maintaining the showerhead at a first temperature; controlling conditions within the processing chamber such that the film precursor is adsorbed onto a substrate held on a substrate holder in the processing chamber forming an adsorption-limited layer on the substrate while substantially maintaining the substrate holder at a second temperature, the second temperature being at least 10° C. below the first temperature; removing at least some unadsorbed film precursor from the volume surrounding the adsorbed film precursor; and reacting adsorbed film precursor, after removing unadsorbed film precursor, to form a film layer on the substrate.

### BRIEF DESCRIPTION OF THE DRAWINGS

FIG. 1 is a cross-sectional schematic of a substrate processing apparatus having a processing chamber with a single process station.

FIG. 2 is a schematic of a four-station substrate processing apparatus having a substrate handler robot for loading and unloading substrates from two process stations and a controller for operating the apparatus.

FIG. 3A presents the results of depositing (via ALD) on a batch of 50 wafers interrupted by a remote plasma clean after the first 25.

FIG. 3B is a plot of “thickness delta” (change in deposited film thickness pre- and post-remote plasma clean) versus showerhead temperature for pedestal temperature set-points of 50, 60, and 70° C.

FIG. 3C is a plot of “thickness delta” versus showerhead temperature resulting from several processes employing showerhead temperature adjustment and one process not employing showerhead temperature adjustment.

FIG. 3D presents a plot and linear fit of deposited film thickness versus pedestal temperature set-point in the absence of contemporaneous showerhead heating.

FIG. 3E presents a plot and linear fit of deposited film thickness versus pedestal temperature set-point in the presence of contemporaneous showerhead heating to 80° C.

FIG. 4A is a cross-sectional view of a showerhead having a thermal adjustment and/or control feature.

FIG. 4B is another cross-sectional view of a showerhead having a thermal adjustment and/or control feature emphasizing aspects other than those emphasized in FIG. 4A.

FIG. 4C is another cross-sectional view of a showerhead having a thermal adjustment and/or control feature emphasizing aspects other than those emphasized in FIGS. 4A-4B.

FIG. 5 is a schematic of a cooling system having a heat exchanger configured to provide cooling to 4 showerheads, or alternatively, it may be configured to provide cooling to 4 substrate holders.

FIG. 6 schematically illustrates a showerhead thermal adjustment/control system.

FIG. 7A is a perspective view of a pedestal-shaped substrate holder having internal heating and cooling elements.

FIG. 7B is a cut-away perspective view of the pedestal-shaped substrate holder of FIG. 7A showing an internal pedestal insert cooling element having a cooling block which is built into the central cylinder of the pedestal.

FIG. 7C is a close-up perspective view of the pedestal insert cooling element of FIG. 7B.

FIG. 7D is a cross-sectional view of a pedestal-shaped substrate holder having internal heating and cooling elements within the face of the showerhead.

FIG. 7E is a cut-away perspective view of the pedestal shaped substrate holder of FIG. 7D showing its internal heating and cooling elements.

FIG. 8 is a flowchart of an example sequence of atomic layer deposition (ALD) operations for forming films having improved consistency through the techniques disclosed herein involving active thermal adjustment and/or control of showerhead and/or substrate holders.

### DETAILED DESCRIPTION

In the following description, numerous specific details are set forth in order to provide a thorough understanding of the present invention. However, the present invention may be practiced without some or all of these specific details. In other instances, well known process operations or hardware have not been described in detail so as to not unnecessarily obscure the inventive aspects of the present work. While the invention will be described in conjunction with specific detailed embodiments, it is to be understood that these specific detailed embodiments are not intended to limit the scope of the inventive concepts disclosed herein.

Disclosed herein are improved methods and apparatuses for depositing films of material via atomic layer deposition (ALD). A semiconductor fabrication step employing the ALD technique to form a film of material typically employs multiple sequential cycles of ALD. A single cycle of ALD only deposits a thin film of material (oftentimes only one molecular layer thick). To build up a film of an appreciable desired thickness, multiple ALD cycles can be performed. Hence there exists the concept of an “ALD cycle” which is sequentially repeated. As described in detail below, a basic ALD cycle for depositing a single layer of material on a substrate in a processing chamber may include: (i) adsorbing a film precursor onto a substrate such that it forms an adsorption-limited layer, (ii) removing (at least some) unadsorbed film precursor from the volume surrounding the adsorbed precursor, and (iii) after removing unadsorbed film precursor, reacting the adsorbed film precursor to form a film layer on the substrate. Oftentimes, an ALD cycle additionally involves an operation of (iv) removing desorbed film precursor and/or reaction by-product from the volume surrounding the layer of film formed on the substrate, when present after reacting the adsorbed film precursor. The removing in operations (ii) and (iv) may be done via purging, evacuating by pumping down to a base pressure (“pump-to-base”), etc. the volume surrounding the substrate. In some embodiments, these purges may be logically divided into what is referred to herein as a “primary purge” or “burst purge” and a “secondary purge.” (The use of primary/burst and secondary purges are described in detail in U.S. patent application Ser. No. 14/447,203 filed Jul. 30, 2014, titled “METHODS AND APPARATUSES FOR SHOWERHEAD BACKSIDE PARASITIC PLASMA SUPPRESSION IN A SECONDARY PURGE ENABLED ALD SYSTEM,” which is incorporated by reference herein in its entirety for all purposes.) Operations (i)-(iii)—and in some embodiments also (iv)—therefore constitute a single cycle of ALD which may then be repeated one or more times to deposit additional layers of film on the substrate, and to thereby build up a film of appreciable thickness as desired.

Because multiple ALD cycles are performed to deposit a film of material—and moreover performed repeatedly over many semiconductor substrates (in a typical wafer fabrication process flow) to deposit onto multiple substrates—it is important that each ALD cycle be controllable, predictable, and repeatable so that the resulting deposited films have uniform compositions and consistent thicknesses. Thus, it is desirable to minimize both the “within wafer” variability of a deposited film (e.g., variations in the thickness of a deposited film at different distinct points on the wafer surface), as well as the variation in the deposited films between wafers in a given batch. Typically, in addition to controlling film precursor and/or co-reactant compositions and flow rates into a reaction process chamber, repeatability of the film deposition process also involves maintaining control of the environmental conditions within the processing chamber.

Temperature within the processing chamber, and even more particularly, the temperature of the substrate upon which the film is being deposited, typically has a significant influence on the consistency of the film formed in an ALD process. For instance, in certain low-temperature (e.g., 50° C.) ALD processes, significant temperature variation in the pedestal/wafer/showerhead system is induced by the ALD process itself. E.g., plasma activation in operation (iii) above—in embodiments where plasma activation is employed—may lead to “plasma heating” of the substrate or processing chamber. Other operations, performed between ALD operations on a given wafer or between the processing of different wafers—such as a chamber clean operation—may also result in temperature fluctuation within the processing chamber. As a result, as described below, non-negligible deposition rate changes have been observed (which, as stated, is undesirable in conformal film applications).

However, it has been found that substrate temperature during film formation may be affected, and to a certain extent stabilized and controlled, through temperature adjustment of various hardware components having thermal contact with the interior volume of the processing chamber. In particular, active thermal adjustment (active heating or cooling) of the showerhead used to dispense film precursor (and/or co-reactants), as well as active thermal adjustment of the pedestal upon which the substrate is held (more generally referred to as a substrate holder), provide mechanisms by which the thermal behavior and characteristics of the substrate may be modified during ALD processes. For instance, as described in detail below, in some embodiments, it has been found that substantially maintaining the showerhead at an elevated temperature above the temperature at which the substrate holder is maintained, say by at least about 5 or 10 or 15 or 20° C. for example, may lead to improved thermal stability of the substrate and to greater consistency of the films deposited via ALD processes.

The foregoing temperature differentials between showerhead and substrate holder may be maintained by actively thermally adjusting and/or controlling showerhead temperature and, in some embodiments, also employing such active thermal adjustment/control of the substrate holder temperature. Thus, in some embodiments, the showerhead may be operated at a higher temperature through active heating while the substrate holder (for example, a pedestal-type device) may be independently operated at a depressed/lower temperature through active cooling. In sum, in such an ALD process, a film precursor may be flowed into a processing chamber through a showerhead while the showerhead is substantially maintained at a first temperature, and then the film precursor may be adsorbed onto a substrate held on a substrate holder in the processing chamber while the substrate holder is substantially maintained at a second temperature which is different (and lower) than the first temperature.

For instance the first temperature (the temperature of the showerhead) may be chosen, selected, programmed, set, maintained, etc. above the second temperature (the temperature of the substrate holder). For example, the first temperature may be at least about 5° C. above the second temperature, or at least about 10° C. above the second temperature, or at least about 15° C. above the second temperature, or at least about 20° C. above the second temperature, or even at least about 30° C. above the second temperature. In some embodiments, the difference between the first and second temperatures may fall within a range of possible temperature difference values. Thus, for example, in some embodiments, the difference between the first and second temperatures may be between about 5 and 30° C., or between about 10 and 20° C., or between about 10 and 15° C., or between about 15 and 20° C., or between about 5 and 20° C., or between about 10 and 30° C., etc. More generally, depending on the embodiment, the difference between the first and second temperatures may fall within a range of values defined by any pair of the following temperature difference values: 5, 10, 15, 20, 25 and 30° C. Thus, for example, the first temperature may be between about 10 and 20° C. above the second temperature, or the first temperature may be between about 15 and 30° C. above the second temperature, etc.

While the temperature difference may be significant, the absolute temperature may also be significant. Thus, for instance, in some embodiments, the second temperature (the temperature of the substrate holder) may be between about 20 and 100° C., or between about 30 and 70° C., or between about 35 and 65° C., or between about 40 and 60° C., or between about 45 and 55° C., or between about 48 and 52° C. More generally, depending on the embodiment, the temperature of the substrate holder substantially maintained during a preferred ALD process may fall within a range of possible temperatures including ranges defined by any pair of the following temperatures: 20, 30, 35, 40, 45, 50, 55, 60, 65, 70, 80, 90 and 100° C. Moreover, in some embodiments, the foregoing measures may stabilize the temperature of the substrate such that it varies by less than about 2° C. during operations (i)-(iii) and/or (iv) above, or even by less than about 1° C. during these operations. Likewise, in some embodiments, the foregoing measures may stabilize the temperature of the showerhead such that it varies by less than about 2° C. during operations (i)-(iii) and/or (iv) above, or even by less than about 1° C. during these operations.

In this manner, depending on the embodiment, one the one hand the showerhead may be operated in a temperature regime where it is not as sensitive to plasma heating and heating due to chamber cleaning related etch processes, while at the same time the substrate may be kept at a lesser temperature which is appropriate for the low temperature ALD process being performed. In so doing, consistency and stability of ALD deposition rate from wafer to wafer—and from wafer batch to wafer batch—may be significantly improved relative to the deposition rate in the absence of active thermal adjustment/control. Other potential advantages may also relate to the added flexibility provided by independent temperature control of the pedestal and showerhead system. Thermal adjustment/control capability and/or temperature choice may generally provide useful additional parameters for process tuning and reducing defect levels—for example, raising the temperature of the showerhead may reduce or eliminating the risk of precursor condensation on the showerhead.

Alternatively, in other embodiments, the showerhead and substrate holder may be thermally adjusted and/or controlled so as to maintain the showerhead at a temperature about or below that of the substrate holder. In this latter embodiment, active cooling is used to remove plasma-generated heat load from the showerhead thereby promoting its thermal stability. In this regime, active cooling of the substrate (via an actively cooled pedestal, for example) may be unneeded since no heat is being thermally conducted to it from a higher-temperature showerhead—i.e., the temperature of the showerhead (identified as the first temperature above) would be about or below the temperature of the substrate holder (identified as the second temperature above).

Thus, depending on the embodiment, the first temperature may be chosen/selected/programmed/set/maintained/etc. below the second temperature, for example, the first temperature may be at least about 5° C. below the second temperature, or at least about 10° C. below the second temperature, or at least about 15° C. below the second temperature, or even at least about 20° C. below the second temperature. In some embodiments, the difference between the first and second temperatures may fall within a range of possible temperature difference values. Thus, for example, in some embodiments, the difference between the first and second temperatures may be between about 5 and 20° C., or between about 10 and 20° C., or between about 10 and 15° C., or between about 15 and 20° C., or between about 5 and 15° C., or between about 5 and 10° C., etc. And also, while the temperature difference between showerhead and substrate holder may be significant in these embodiments where the showerhead is kept colder than the substrate holder, the absolute temperatures involved may also be significant. Thus, for instance, the possible substrate holder temperature ranges described above may also be applicable to these colder showerhead embodiments, depending on the specific configuration, for example, how much thermal control and cooling capability is available. And, the corresponding temperature variations at the actual substrate may also be as described above, +/−1° C. for example, as described above.

Overview of Film Deposition Apparatuses

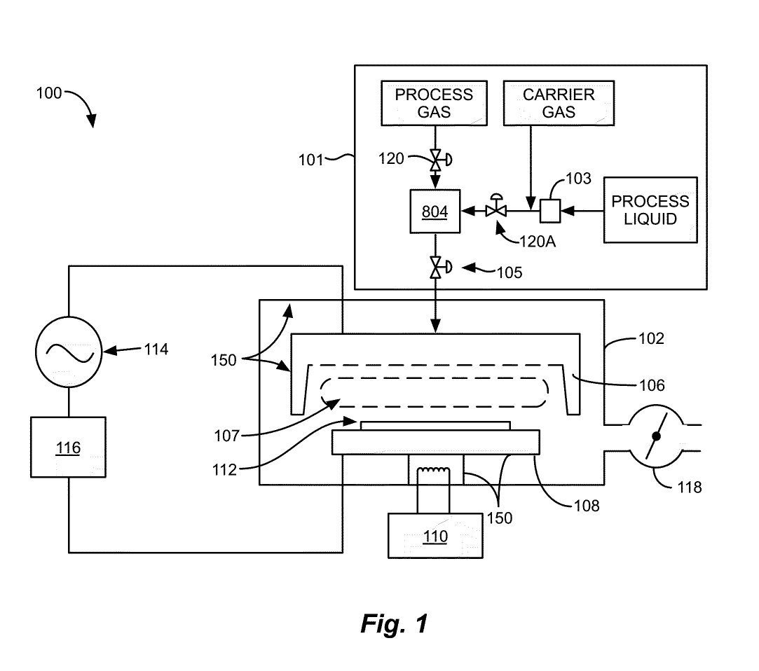

Operations for depositing films on semiconductor substrates may generally be performed in a substrate processing apparatus like that shown in FIG. 1. The apparatus 100 of FIG. 1, which will be described in greater detail below, has a single processing chamber 102 with a single substrate holder 108 in an interior volume which may be maintained under vacuum by vacuum pump 118. Also fluidically coupled to the chamber for the delivery of (for example) film precursors, carrier and/or purge and/or process gases, secondary/co-reactants, etc. is gas delivery system 101 and showerhead 106. Equipment for generating a plasma within the processing chamber is also shown in FIG. 1 and will be descried in further detail below. In any event, as it is described in detail below, the apparatus schematically illustrated in FIG. 1 provides the basic equipment for performing film deposition operations such as ALD on semiconductor substrates.

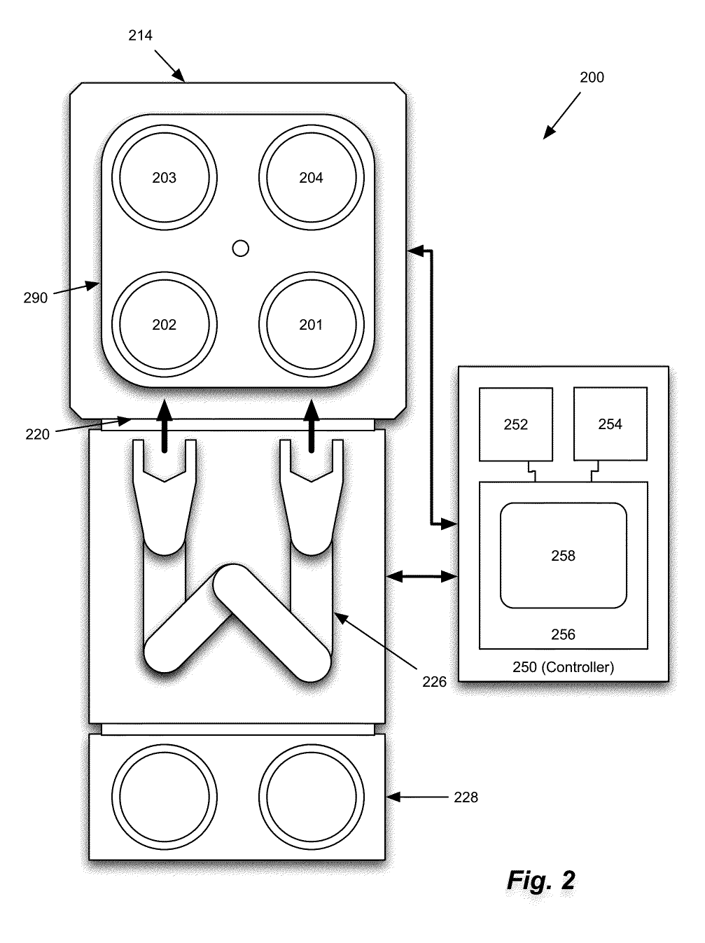

While in some circumstances a substrate processing apparatus like that of FIG. 1 may be sufficient, when time-consuming film deposition operations are involved, it may be advantageous to increase substrate processing throughput by performing multiple deposition operations in parallel on multiple semiconductor substrates simultaneously. For this purpose, a multi-station substrate processing apparatus may be employed like that schematically illustrated in FIG. 2. The substrate processing apparatus 200 of FIG. 2, still employs a single substrate processing chamber 214, however, within the single interior volume defined by the walls of the processing chamber, are multiple substrate process stations, each of which may be used to perform processing operations on a substrate held in a wafer holder at that process station. In this particular embodiment, the multi-station substrate processing apparatus 200 is shown having 4 process stations 201, 202, 203, and 204. The apparatus also employs a substrate loading device, in this case substrate handler robot 226, for loading substrates at process stations 201 and 202, and a substrate transferring device, in this case substrate carousel 290, for transferring substrates between the various process stations 201, 202, 203, and 204. Other similar multi-station processing apparatuses may have more or fewer processing stations depending on the embodiment and, for instance, the desired level of parallel wafer processing, size/space constraints, cost constraints, etc. Also shown in FIG. 2 and described in greater detail below is controller 150. In some embodiments, controller 150 may adjust and/or control the temperature(s) of the showerhead(s), substrate holder(s) (e.g., pedestal(s)), and/or chamber wall(s), etc. and, in so doing, assist the goal of performing consistent and repeatable substrate deposition operations between multiple wafers and multiple batches of wafers (undergoing ALD operations).

Note that various efficiencies may be achieved through the use of a multi-station processing apparatus like that shown in FIG. 2 with respect to both equipment cost and operational expenses. For instance, a single vacuum pump (not shown in FIG. 2, but e.g. 118 in FIG. 1) may be used to evacuate spent process gases, create a single high-vacuum environment, etc. with respect to all 4 process stations. Likewise, in some embodiments, a single showerhead may be shared amongst all processing stations within a single processing chamber.

However, in other embodiments, each process station may have its own dedicated showerhead for gas delivery (see, e.g., 106 in FIG. 1), although in certain such embodiments a common gas delivery system may be employed (e.g., 101 in FIG. 1). In embodiments having a dedicated showerhead per process station, each may have its temperature individually adjusted and/or controlled. For instance, each showerhead may be temperature adjusted relative to the substrate to which it delivers gases, or relative to the substrate holder with which it is associated, etc. By the same measure, in embodiments where substrate holders are actively temperature controlled/adjusted, via heating and/or cooling for instance, the temperature of each substrate holder may be individually adjusted.

Other hardware elements which may be shared amongst process stations or multiply present and individually dedicated per process station include certain elements of the plasma generator equipment. All process stations may share a common plasma power supply, for example, but, on the other hand, if dedicated showerheads are present, and if they are used to apply plasma-generating electrical potentials—see the discussion of FIG. 1 below—then these represent elements of the plasma generating hardware which are individually dedicated to the different process stations. Once again, each of these process station-specific showerheads may have its temperature individually adjusted according to, for example, differences in the thermal properties of the specific process stations and the particulars of the ALD processes being used. Of course, it is to be understood that such efficiencies may also be achieved to a greater or lesser extent by using more or fewer numbers of process stations per processing chamber such as 2, 3, 5, 6, 7, 8, 9, 10, 11, 12, 13, 14, 15, or 16, or more process stations per reaction chamber.

Improvement in Deposition Rate Consistency and Uniformity Through Showerhead and/or Substrate Holder Temperature Adjustment and/or Control

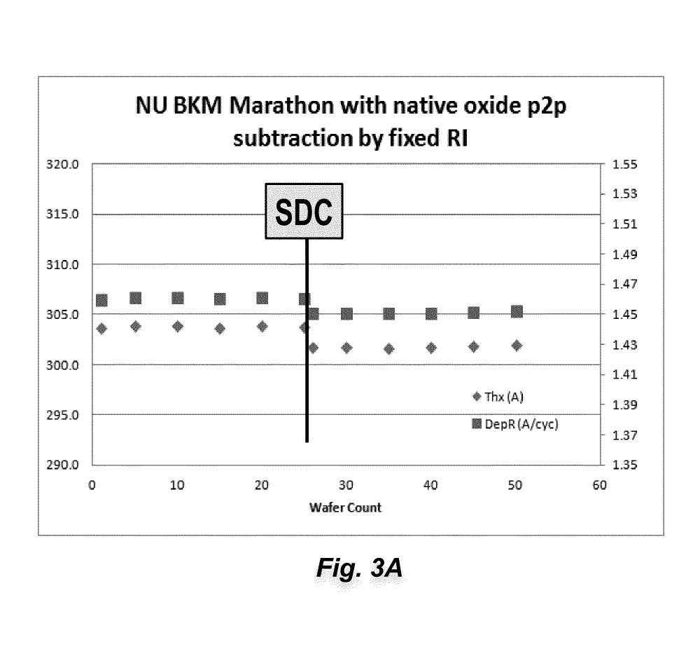

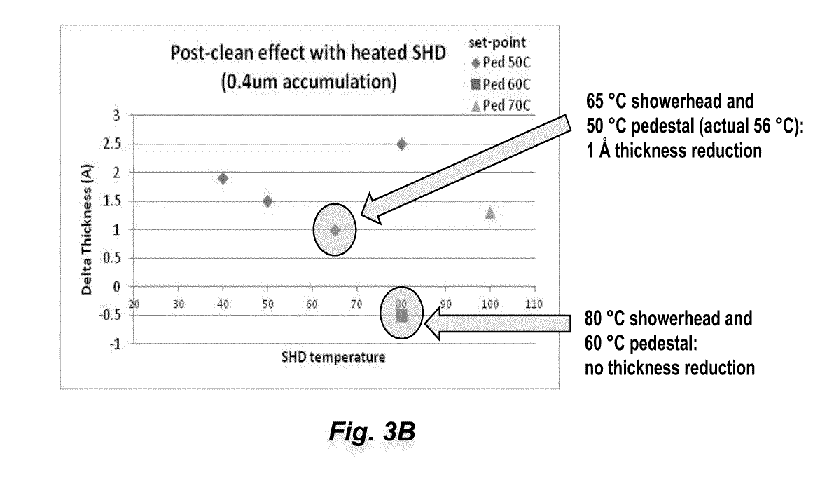

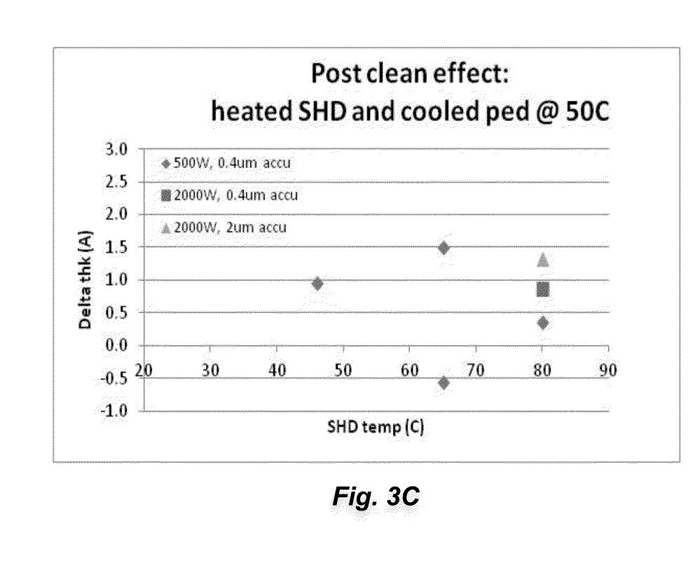

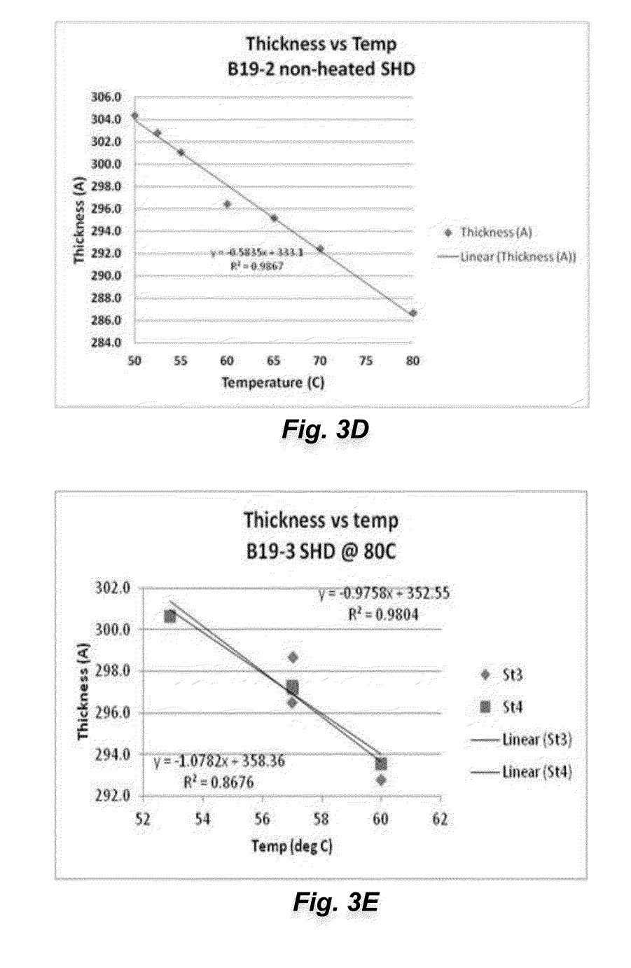

Uniformity of sequentially performed ALD processes depends on the maintenance of consistent environmental process conditions within the processing chamber volumes employed. However, it has been found, for example, that temperature fluctuations within a processing chamber resulting from a remote plasma clean (RPC) operation can alter conditions leading to undesired variability in deposited films. FIG. 3A, for instance, shows the results of depositing (via ALD) on a batch of 50 wafers interrupted by a remote plasma clean (RPC) after the first 25. The figure illustrates a distinct drop in the deposition rate and deposited film thickness immediately subsequent to the RPC (i.e., going from wafer numbers 25 to 26). Specifically, the thickness drop shown in FIG. 3A after a 20 minute RPC was found to be −1.8 Å. In another experiment involving a 1 hour, 40 minute RPC after deposition onto 500 wafers, the thickness drop was found to be 6.0 Å illustrating that, at least in this case, longer cleaning times result in greater variation in deposited film thickness (i.e., “thickness delta”) and corresponding deposition (“dep”) rate.

The results of these and further experiments dealing with remote plasma cleans are shown in Table I along with related comments. Specifically, Table I lists a sequence of operations/processes performed on a series of wafers illustrating the effects of remote plasma “Clean” operations and the effects of various other process operations, such as showerhead heating and cooling test, at ameliorating the variation caused by the clean steps. Operation 1 in the table corresponds to what is shown in FIG. 3A and just described. Operation 2 shows that cooling the showerhead by filling the chamber to 8 Torr with He gas for 3 hours reduces the thickness delta caused by the cleaning operation to 0.5 Å, or less than ⅓ of the thickness variation in the absence of cooling with He. However, a 3 hour break to cool the showerhead after processing only 25 wafers is clearly undesirable from the standpoint of throughput. Operation 3 shows the effect of running an Ar/N₂ plasma within the chamber and that it does not lead to significant thickness variability. However, Operations 4 and 5 show that running an N₂0 plasma—known to generate significant heating—for 6 minutes, or for just 2 minutes after a cleaning operation, leads to significant thickness variability (thicknesses deltas of 1.3 Å and 2.2 Å, respectively).

Processes 6-9 show the effects of a higher-pressure, 18 Torr, Helium flow through the showerhead to cool the showerhead subsequent to a cleaning operation. The results show that the use of a higher pressure helium flow does reduce time required for showerhead cooling to the order of an hour—versus the 8 hour cooling used in Operation 2 for an 8 Torr He flow—but that it still does not completely eliminate the cleaning induced variability in dep rate. Furthermore, Operations 10-14 move to a 500 wafer run and a subsequent extended cleaning of 1 hour, 20 minutes (resulting in a 6.0 Å thickness delta, as mentioned above) and here, in this regime, it is seen that it takes 2 hours of He cooling (via the chamber being filled with 18 Torr of Helium) to eliminate the non-uniformity—which is, once again, unacceptable from a processing throughput standpoint. Finally, Operation 15 runs an RPC on a chamber which is already clean, and no thickness delta results, indicating no showerhead heating has occurred. This tends to indicate that the heating from the RPC is caused by the exothermic etch itself of the film accumulated in the chamber (which is the purpose of the clean).

Thus, Table I illustrates that the variability in deposition thicknesses and rates following a remote plasma clean (RPC) does seem to result from a change in chamber environmental conditions due to the RPC—specifically temperature, as is shown by the fact that He cooling is able to (after a not insignificant time) restore deposition rates and thicknesses to their pre-RPC values.

TABLE I

| | | Thickness | |
|---|---|---|---|
| # | Operation/Process | Delta | Comments |
| 1 | 25 wfr→Clean→25 wfr | 1.8 Å | |
| 2 | He, 8 Torr Cooling 3 hr | 0.5 Å | 25 wfr→Clean, cool→25 wfr |
| 3 | Ar/N₂ Plasma | 0.1 Å | 25 wfr→Plasma→25 wfr |
| 4 | N₂O Plasma, 6 min | 1.3 Å | 25 wfr→Plasma→25 wfr |
| 5 | Clean + N₂O Plasma, 2 min | 2.2 Å | 25 wfr→Clean, Plasma→25 wfr |
| 6 | He, 18 Torr, 30 min | 1.6 Å | 25 wfr→Clean, Cool→25 wfr, 15 min Idle |
| 7 | He, 18 Torr, 1 hr MG) | 0.5 Å | 25 wfr→Clean, Cool→25 wfr, 30 min Idle |
| 8 | He, 18 Torr, 1 hr (PC) | 1.2 Å | 25 wfr→Clean, Cool→25 wfr, |
| 9 | He, 18 Torr, 1.5 hr (PC) | 0.3 Å | 25 wfr→Clean, Cool→25 wfr, 10 min Idle |
| 10 | 500 wfr→Clean→500 wfr | 5.8 Å, 6.0 Å | 2 hr Idle after 1^{st} marathon, |
| 11 | 2 h, He Cool | 2.8 Å | |
| 12 | 3 h, He Cool | ~0 Å | 0.8 Å delta seen in the next marathon |
| 13 | 4 h, He Cool | −0.6 Å | Thickness increased |
| 14 | 5 h, He Cool | −1.2 Å | Thickness increased |
| 15 | RPC Clean of Same duration as | ~0 Å | |
| | after 25 wfr run | | |

While the experimental results shown in Table I illustrate the dilemma, they do not suggest how to eliminate thickness variability while at the same time maintaining high wafer throughput processing operations. An entirely different approach to the problem is to employ a processing apparatus design wherein the showerhead does not exhibit temperature variation due to deposition processes or intervening cleaning operations. Insulating the showerhead from thermal energy generated within the processing chamber is one such approach. Another approach is to employ a processing apparatus where the showerhead is actively cooled so that although it may be exposed to significant quantities of thermal energy, the thermal energy is conducted away before it can lead to increases in showerhead temperature. A third approach that almost appears inapposite to the foregoing (and to what is illustrated by the experiments in Table I) is to purposefully heat the showerhead to an elevated temperature so that thermal energy generated by deposition or cleaning operations does not significantly alter its temperature.

Table II shows the results of experiments designed to determine appropriate ranges of showerhead (SHD) operating temperatures to accomplish this third approach. The substrate processing apparatus used for this experiment was a 4 process station apparatus (e.g., similar to that shown in FIG. 2) with a dedicated showerhead for each station (as described above). Shown in Table II are the temperatures of the showerheads associated with process stations 3 and 4 as well as the temperatures of the 4 pedestals 1-4 (serving as wafer holders).

Operation 1 establishes the baseline temperatures, with both showerheads 3 and 4 at 38° C. and the 4 pedestals heated to 50° C. In operation 2 an N₂O plasma was applied for ½ minute, resulting in a nominal heating of SHD 3 and no change of temperature for SHD 4. However, in subsequent Operation 3, a timed remote plasma clean is performed (in two steps, for 300 seconds and then 600 seconds, rather than until a particular endpoint is detected as in the other RPC cleans mentioned here) resulting in a significant 17° C. increase in temperature at both showerheads 3 and 4.

(Note that showerheads 3 and 4 were instrumented with thermocouples so there temperatures could be directly measured throughout these operations.) Additional plasma processes in operations 4-6 then show that plasma processes also lead to temperature increases at the showerhead. Specifically, application of N₂O plasma for 2 minutes, 6 minutes, and 10 minutes in operations 4, 5, and 6 respectively lead to significant temperature increases, up to 125° C. at showerhead 3 and 68° C. at showerhead 4 in operation 6. The differential temperature changes between showerheads 3 and 4 result from a factor of 3 difference in plasma power between stations 3 and 4. These results illustrate once again that both process plasma application as well as remote plasma clean (RPC) operations result in showerhead heating. Operation 7, as in Table I, confirms that He cooling does indeed restore showerhead temperatures to near their baseline values. That the pedestal temperatures remain stable through these plasma treatments is supported by their stable and consistent readings in operation 5 (though the temperature at pedestal 3 is about 3° C. higher likely due to the higher plasma powers in use at station 3).

Operations 8 and 9 then illustrate once again that deposition processes—here a sequence of 25 wafers are deposited upon with a 500 watt plasma activation step—followed by remote plasma clean do progressively raise showerhead temperatures (again, more so at station 3), but do not have a strong effect on the temperature controlled pedestals. It is seen that the increase in showerhead temperature is between about 10-20° C. depending on processing station. However, after another subsequent helium cooling in operation 10, it is seen that an operation of depositing 4 μm of SiO₂ film followed by remote plasma clean results in a consistent increase in temperature of 20° C. at both stations 3 and 4 while the pedestals remain at 50° C. One concludes that in the absence of temperature adjustment and/or control, the showerheads may be expected to go from being about 10° C. below the 50° C. set temperature of the pedestals to being about 10-20° C. higher than the set pedestal temperatures.

TABLE II

| | | SHD 3 | SHD 4 | Pedestals 1-4 |
|---|---|---|---|---|
| # | Operation/Process | (° C.) | (° C.) | (° C.) |
| 1 | SHD long Idle Base Line | 38 | 38 | 50, 50, 50, 50 |
| 2 | N₂O Plasma, | 41 | 38 | |
| | 0.5 min | | | |
| 3 | 300/600 timed RPC | 58 | 55 | |
| | Clean | | | |
| 4 | N₂O Plasma, | 66 | 55 | |
| | 2 min | | | |
| 5 | N₂O Plasma, | 89 | 61 | 51.8, 51.7, 54.8, 50.9 |
| | 6 min | | | |
| 6 | N₂O Plasma, | 125 | 68 | |
| | 10 min | | | |
| 7 | He, 18 Torr Cooling | 41 | 41 | |
| 8 | After 25 wafer 500 W | 55 | 43 | |
| 9 | RPC Clean | 61 | 54 | 50, 50, 50, 50 |
| 10 | He, 18 T Cooling | 40 | 41 | |
| 11 | After 4 μm accumulation | 51 | 44 | 50.1, 50.1, 50.1, 50.3 |
| 12 | RPC Clean | 82 | 81 | 51, 51, 52.2, 50.9 |

In view of Table II, various showerhead and pedestal temperature combinations were used in a series of ALD experiments to assess the capability of each combination to minimize the variability in dep rate and film thickness pre- and post-RPC. FIG. 3B displays the results. Specifically, FIG. 3B presents a plot of “thickness delta” (change in deposited film thickness pre- and post-RPC after 4 μm SiO₂ deposition) versus showerhead temperature for pedestal temperature set-points of 50, 60, and 70° C. The data reveals two showerhead/pedestal temperature combinations which resulted in a thickness delta of about 1 Å or less: a 65° C. showerhead with ˜50° C. pedestal (actual temperature of 56° C.) achieved a thickness delta of less than 1 Å; and an 80° C. showerhead with 60° C. pedestal resulted in essentially no thickness reduction pre- and post-RPC. The former represents a showerhead temperature of 9° C. above the actual pedestal temperature or about 15° C. above the pedestal temperature set-point, and the latter represents a showerhead temperature of 20° C. above the pedestal temperature set-point. (Note, for both of these cases, the pedestal temp increased by ˜1° C. between pre- and post-clean.) Thus, these examples illustrate that by adjusting the temperature of the showerhead such that it is at least about 10° C. above the substrate temperature and/or pedestal temperature set-points one may significantly reduce pre/post-clean dep rate variations in ALD processes.

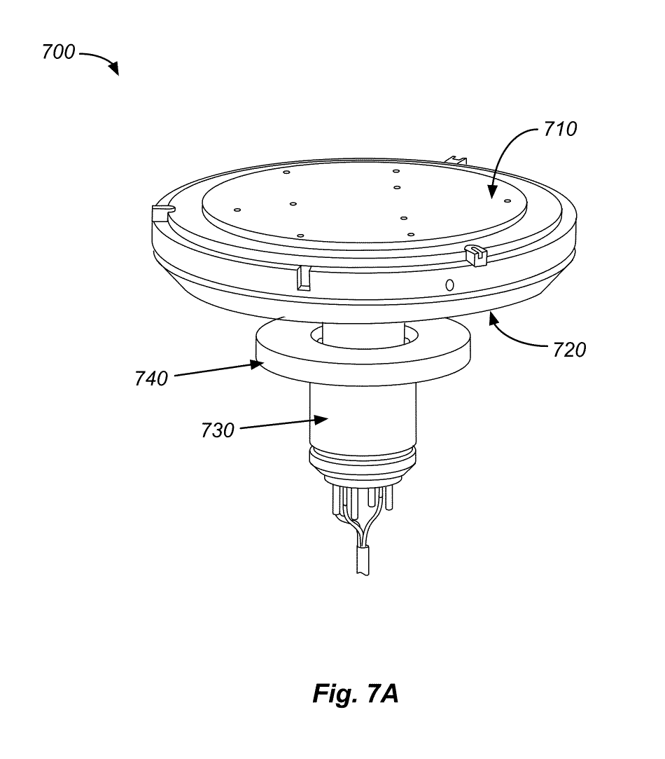

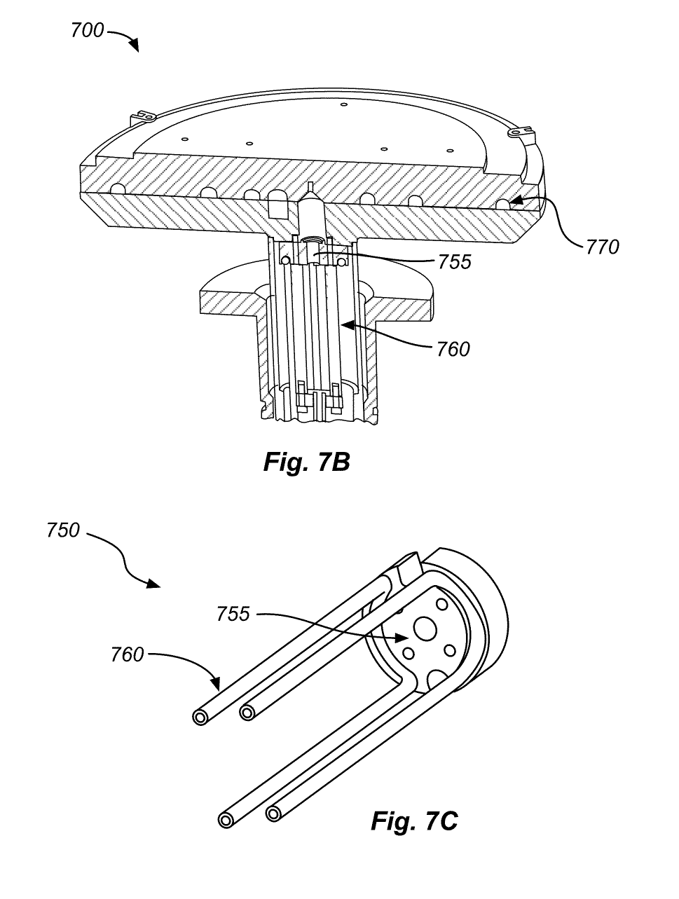

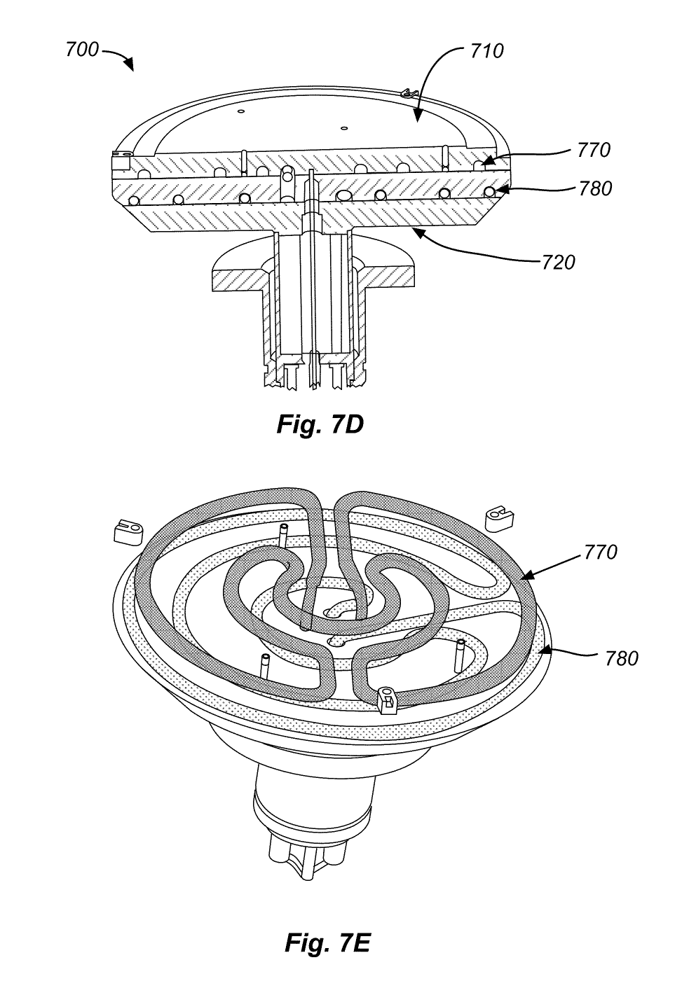

In yet other embodiments, one may employ a mechanism for active substrate holder (e.g., pedestal) cooling within a substrate processing chamber in order to reduce dep variation in ALD processes. This may be done with or without contemporaneous showerhead thermal adjustment/control, depending on the embodiment. In one embodiment, such active pedestal cooling may be accomplished by the use of a cooled lower chamber wall, which may have its desired effect by acting as a sink for thermal diffusion of heat away from the pedestal and substrate. In other embodiments, it may be more convenient and at least equally effective is to use a pedestal having an internal mechanism for active cooling. For example, a pedestal having internal conduits for flowing a cooling fluid through the pedestal structure directly may thereby result in the cooling fluid have its cooling effect more immediately on the pedestal and substrate. An example of an actively-cooled pedestal employing separate conduits for circulating cooling and heating fluids is described below and schematically illustrated in FIGS. 7A-7E.

In one series of examples, Table III lists the thickness deltas resulting from employing a mechanism for active pedestal cooling. This is done through circulating chilled water through the pedestal itself or, where indicated in the table, through the use of actively cooled chamber walls. In either hardware configuration, the effect is essentially to provide additional active cooling to the pedestal so as to improve temperature control at the 50° C. set-point. This may be understood from the standpoint that if one is to supply sufficient temperature control to the substrate itself, then thermal stability of the showerhead is not as critical. However, Table III still also illustrates that improved thickness deltas are obtained if showerhead temperature control is exercised as well. For instance, the thickness delta associated resulting from process 3—not employing showerhead temperature adjustment—is at the desired 1 Å target level, however processes 1 and 2—employing 80° C. and 60° C. showerhead temperature set-points—achieve lower than 1 Å thickness deltas. These results are graphically plotted in FIG. 3C. Process 4 ups the plasma power by a factor of 4 to 2000 Watts, yet the thickness delta of ˜0.8 Å shows that this combination of showerhead and pedestal temperature set-points is able to handle the higher plasma power. Accumulating deposition to 2 μm in process 5—using the same temperature set-points and plasma power as in process 4—results in a thickness delta increase from 1 to 1.3 Å, which is effectively negligible within typical measurement error bars, showing that good dep rate control from batch to batch is maintained at larger batch size (2 μm). These results are also graphically plotted in FIG. 3C. Comparing FIG. 3C with FIG. 3B, it is seen that utilizing active cooling of the pedestal in combination with a temperature-adjusted showerhead (FIG. 3C) does a better job of keeping pre-/post-clean thickness deltas within the desired 1 Å target window than does employing a temperature-adjusted showerhead alone (FIG. 3B).

TABLE III

| | | Target | | | | |
|---|---|---|---|---|---|---|
| | | Thickness | Plasma | Pedestal | Showerhead | Thickness |
| | | Accumulation | power | Set-Point | Set-Point | Delta |
| # | Process | (μm) | (Watts) | (° C.) | (° C.) | (Å) |
| 1 | 25 wfr→Clean→25 wfr | 0.4 | 500 | 50* | 80 | 0.3 |
| 2 | 25 wfr→Clean→25 wfr | 0.4 | 500 | 50* | 65 | −0.6 |
| 3 | 25 wfr→Clean→25 wfr | 0.4 | 500 | 50* | None | 1 |
| 4 | 25 wfr→Clean→25 wfr | 0.4 | 2000 | 50* | 80 | 0.8 |
| 5 | 250 wfr→Clean→250 wfr | 2 | 2000 | 50* | 80 | 1.3 |

[*Accomplished using cooled chamber walls]

In order to better understand the basis of the beneficial effect provided by employing improved temperature control of the substrate holder (e.g., by employing a cooled lower chamber wall), an additional series of experiments were carried out which measured deposited film thickness as a function of pedestal temperature set-point, in the presence and absence of contemporaneous showerhead heating. FIG. 3D plots the results of these experiments performed without showerhead heating, and FIG. 3E plots the results with contemporaneous showerhead heating to 80° C. In both cases, a negative linear relationship is exhibited between deposited film thickness and pedestal temperature set-point, however, the slopes of the best fit lines for the case of the 80° C. heated showerhead are approximately double that of the unheated showerhead (cf. −0.9758 and −1.0782 Å/° C. versus −0.5835 Å/° C.). In other words, the data reveals that dep rates are more strongly retarded by increased pedestal temperature in the presence of a heated showerhead. The reason is postulated as follows: Without heating from the showerhead, the wafer will generally have a temperature somewhat below that set at the pedestal, and so the effect of pedestal heating on dep rate is somewhat diminished. In contrast, when the showerhead is actively heated to a temperature higher than that of the pedestal, the wafer will also generally then have a temperature higher than that of the pedestal, and accordingly heating from the pedestal will have a more pronounced and undiminished effect. For these reasons, the further reduction in pre-/post-clean thickness delta associated with the use of cooled lower chamber walls in conjunction with a heated showerhead may be understood to be a consequence of this tendency of the substrate to more strongly adsorb thermal energy from the pedestal when the showerhead is heated.

These experiments thus suggest that in an apparatus employing a heated showerhead, substrate temperature control is of greater importance. To confirm that the addition of cooled lower chamber walls provides such enhanced temperature control, several additional measurements were made which are listed in Table IV. Table IV lists measured actual pedestal temperatures and film thicknesses deposited at two process stations (stations 3 and 4) of an apparatus employing cooled lower chamber walls. Temperature and deposited film thickness are compared at two showerhead temperature set-points—65° C. and 80° C. The advantage of employing cooled lower chamber walls is confirmed by the data in Table IV showing that both showerhead set-points result in consistent actual pedestal temperatures and film thicknesses. Specifically, this data and that presented above suggest that to maintain pre-/post-clean thickness delta within a 1 Å tolerance window, it may be beneficial to keep pedestal temperature controlled to within +/−1° C. while the showerhead is heated to several degrees above the pedestal temperature.

TABLE IV

| | Pedestal | Showerhead | Deposited Film |
|---|---|---|---|
| Station | Temperature (° C.) | Set-Point (° C.) | Thickness (Å) |
| 4 | 57 | 80 | 297.3 |
| 3 | 57 | 80 | 296.5 |
| 4 | 56 | 65 | 297.4 |
| 3 | 56 | 65 | 297.0 |

Detailed Description of Atomic Layer Deposition Techniques and Deposited Films

As discussed above, as devices sizes continue to shrink and ICs move to employing 3-D transistors and other 3-D structures, the ability to deposit a precise amount (thickness) of conformal film material—dielectrics in particular, but also various dopant-containing materials—has become increasingly important. Atomic layer deposition is one technique for accomplishing conformal film deposition that typically involves multiple cycles of deposition in order to achieve a desired thickness of film.

In contrast with chemical vapor deposition (CVD) process, where activated gas phase reactions are used to deposit films, ALD processes use surface-mediated deposition reactions to deposit films on a layer-by-layer basis. For instance, in one class of ALD processes, a first film precursor (P1) is introduced in a processing chamber in the gas phase, is exposed to a substrate, and is allowed to adsorb onto the surface of the substrate (typically at a population of surface active sites). Some molecules of P1 may form a condensed phase atop the substrate surface, including chemisorbed species and physisorbed molecules of P1. The volume surrounding the substrate surface is then evacuated to remove gas phase and physisorbed P1 so that only chemisorbed species remain. A second film precursor (P2) may then be introduced into the processing chamber so that some molecules of P2 adsorb to the substrate surface. The volume surrounding the substrate within the processing chamber may again be evacuated, this time to remove unbound P2. Subsequently, energy provided to the substrate (e.g., thermal or plasma energy) activates surface reactions between the adsorbed molecules of P1 and P2, forming a film layer. Finally, the volume surrounding the substrate is again evacuated to remove unreacted P1 and/or P2 and/or reaction by-product, if present, ending a single cycle of ALD.

ALD techniques for depositing conformal films having a variety of chemistries—and also many variations on the basic ALD process sequence—are described in detail in U.S. patent application Ser. No. 13/084,399, filed Apr. 11, 2011, titled “PLASMA ACTIVATED CONFORMAL FILM DEPOSITION” (Attorney Docket No. NOVLP405), U.S. patent application Ser. No. 13/242,084, filed Sep. 23, 2011, titled “PLASMA ACTIVATED CONFORMAL DIELECTRIC FILM DEPOSITION,” now U.S. Pat. No. 8,637,411 (Attorney Docket No. NOVLP427), U.S. patent application Ser. No. 13/224,240, filed Sep. 1, 2011, titled “PLASMA ACTIVATED CONFORMAL DIELECTRIC FILM DEPOSITION” (Attorney Docket No. NOVLP428), and U.S. patent application Ser. No. 13/607,386, filed Sep. 7, 2012, titled “CONFORMAL DOPING VIA PLASMA ACTIVATED ATOMIC LAYER DEPOSITION AND CONFORMAL FILM DEPOSITION” (Attorney Docket No. NOVLP488), each of which is incorporated by reference herein in its entirety for all purposes. As described in these prior applications, a basic ALD cycle for depositing a single layer of material on a substrate may include: (i) adsorbing a film precursor onto a substrate such that it forms an adsorption-limited layer, (ii) removing unadsorbed precursor from the volume surrounding the adsorbed precursor, (iii) reacting the adsorbed-precursor to form a layer of film on the substrate, and (iv) removing desorbed film precursor and/or reaction by-product from the volume surrounding the layer of film formed on the substrate. The removing in operations (ii) and (iv) may be done via purging, evacuating, pumping down to a base pressure (“pump-to-base”), etc. the volume surrounding the substrate. It is noted that this basic ALD sequence of operations (i) through (iv) doesn't necessary involve two chemiadsorbed reactive species P1 and P2 as in the example described above, nor does it even necessarily involve a second reactive species, although these possibilities/options may be employed, depending on the desired deposition chemistries involved.

Due to the adsorption-limited nature of ALD, however, a single cycle of ALD only deposits a thin film of material, and oftentimes only a single monolayer of material. For example, depending on the exposure time of the film precursor dosing operations and the sticking coefficients of the film precursors (to the substrate surface), each ALD cycle may deposit a film layer only about 0.5 to 3 Angstroms thick. Thus, the sequence of operations in a typical ALD cycle—operations (i) through (iv) just described—are generally repeated multiple times in order to form a conformal film of the desired thickness. Thus, in some embodiments, operations (i) through (iv) are repeated consecutively at least 1 time, or at least 2 times, or at least 3 times, or at least 5 times, or at least 7 times, or at least 10 times in a row. An ALD film may be deposited at a rate of about or between 0.1 Å and 2.5 Å per ALD cycle, or about or between 0.2 Å and 2.0 Å per ALD cycle, or about or between 0.3 Å and 1.8 Å per ALD cycle, or about or between 0.5 Å and 1.5 Å per ALD cycle, or about or between 0.1 Å and 1.5 Å per ALD cycle, or about or between 0.2 Å and 1.0 Å per ALD cycle, or about or between 0.3 Å and 1.0 Å per ALD cycle, or about or between 0.5 Å and 1.0 Å per ALD cycle.

In some film forming chemistries, an auxiliary reactant or co-reactant—in addition to what is referred to as the “film precursor”—may also be employed. In certain such embodiments, the auxiliary reactant or co-reactant may be flowed continuously during a subset of steps (i) through (iv) or throughout each of steps (i) through (iv) as they are repeated. In some embodiments, this other reactive chemical species (auxiliary reactant, co-reactant, etc.) may be adsorbed onto the substrate surface with the film precursor prior to its reaction with the film precursor (as in the example involving precursors P1 and P2 described above), however, in other embodiments, it may react with the adsorbed film precursor as it contacts it without prior adsorption onto the surface of the substrate, per se. Also, in some embodiments, operation (iii) of reacting the adsorbed film precursor may involve contacting the adsorbed film precursor with a plasma. The plasma may provide energy to drive the film-forming reaction on the substrate surface. In certain such embodiments, the plasma may be an oxidative plasma generated in the reaction chamber with application of suitable RF power (although in some embodiments, it may be generated remotely). In other embodiments, instead of an oxidative plasma, an inert plasma may be used. The oxidizing plasma may be formed from one or more oxidants such as O₂, N₂O, or CO₂, and may optionally include one or more diluents such as Ar, N₂, or He. In one embodiment, the oxidizing plasma is formed from O₂ and Ar. A suitable inert plasma may be formed from one or more inert gases such as He or Ar. Further variations on ALD processes are described in detail in the prior patent applications just cited (and which are incorporated by reference).

In some embodiments, a multi-layer deposited film may include regions/portions of alternating composition formed, for example, by conformally depositing multiple layers sequentially having one composition, and then conformally depositing multiple layers sequentially having another composition, and then potentially repeating and alternating these two sequences. Some of these aspects of deposited ALD films are described, for example, in U.S. patent application Ser. No. 13/607,386, filed Sep. 7, 2012, and titled “CONFORMAL DOPING VIA PLASMA ACTIVATED ATOMIC LAYER DEPOSITION AND CONFORMAL FILM DEPOSITION” (Attorney Docket No. NOVLP488), which is incorporated by reference herein in its entirety for all purposes. Further examples of conformal films having portions of alternating composition—including films used for doping an underlying target IC structure or substrate region—as well as methods of forming these films, are described in detail in: U.S. patent application Ser. No. 13/084,399, filed Apr. 11, 2011, and titled “PLASMA ACTIVATED CONFORMAL FILM DEPOSITION” (Attorney Docket No. NOVLP405); U.S. patent application Ser. No. 13/242,084, filed Sep. 23, 2011, and titled “PLASMA ACTIVATED CONFORMAL DIELECTRIC FILM DEPOSITION,” now U.S. Pat. No. 8,637,411 (Attorney Docket No. NOVLP427); U.S. patent application Ser. No. 13/224,240, filed Sep. 1, 2011, and titled “PLASMA ACTIVATED CONFORMAL DIELECTRIC FILM DEPOSITION” (Attorney Docket No. NOVLP428); U.S. patent application Ser. No. 13/607,386, filed Sep. 7, 2012, and titled “CONFORMAL DOPING VIA PLASMA ACTIVATED ATOMIC LAYER DEPOSITION AND CONFORMAL FILM DEPOSITION” (Attorney Docket No. NOVLP488); and U.S. patent application Ser. No. 14/194,549, filed Feb. 28, 2014, and titled “CAPPED ALD FILMS FOR DOPING FIN-SHAPED CHANNEL REGIONS OF 3-D IC TRANSISTORS”; each of which is incorporated by reference herein in its entirety for all purposes.

As detailed in the above referenced specifications, ALD processes are oftentimes used to deposit conformal silicon oxide films (SiOx), however ALD processes may also be used to deposit conformal dielectric films of other chemistries as also disclosed in the foregoing incorporated specifications. ALD-formed dielectric films may, in some embodiments, contain a silicon carbide (SiC) material, a silicon nitride (SiN) material, a silicon carbonitride (SiCN) material, or a combination thereof. Silicon-carbon-oxides and silicon-carbon-oxynitrides, and silicon-carbon-nitrides may also be formed in some embodiment ALD-formed films. Methods, techniques, and operations for depositing these types of films are described in detail in U.S. patent application Ser. No. 13/494,836, filed Jun. 12, 2012, titled “REMOTE PLASMA BASED DEPOSITION OF SiOC CLASS OF FILMS,” Attorney Docket No. NOVLP466/NVLS003722; U.S. patent application Ser. No. 13/907,699, filed May 31, 2013, titled “METHOD TO OBTAIN SiC CLASS OF FILMS OF DESIRED COMPOSITION AND FILM PROPERTIES,” Attorney Docket No. LAMRP046/3149; U.S. patent application Ser. No. 14/062,648, titled “GROUND STATE HYDROGEN RADICAL SOURCES FOR CHEMICAL VAPOR DEPOSITION OF SILICON-CARBON-CONTAINING FILMS”; and U.S. patent application Ser. No. 14/194,549, filed Feb. 28, 2014, and titled “CAPPED ALD FILMS FOR DOPING FIN-SHAPED CHANNEL REGIONS OF 3-D IC TRANSISTORS”; each of which is hereby incorporated by reference in its entirety and for all purposes.

Other examples of film deposition via ALD include chemistries for depositing dopant-containing films as described in the patent applications listed and incorporated by reference above (U.S. patent application Ser. Nos. 13/084,399, 13/242,084, 13/224,240, and 14/194,549). As described therein, various dopant-containing film precursors may be used for forming the dopant-containing films, such as films of boron-doped silicate glass (BSG), phosphorous-doped silicate glass (PSG), boron phosphorus doped silicate glass (BPSG), arsenic (As) doped silicate glass (ASG), and the like. The dopant-containing films may include B₂O₃, B₂O, P₂O₅, P₂O₃, As₂O₃, As₂O₅, and the like. Thus, dopant-containing films having dopants other than boron are feasible. Examples include gallium, phosphorous, or arsenic dopants, or other elements appropriate for doping a semiconductor substrate, such as other valence III and V elements.

As for ALD process conditions, ALD processes may be performed at various temperatures. In some embodiments, suitable temperatures within an ALD reaction chamber may range from between about 25° C. and 450° C., or between about 50° C. and 300° C., or between about 20° C. and 400° C., or between about 200° C. and 400° C., or between about 100° C. and 350° C.

Likewise, ALD processes may be performed at various ALD reaction chamber pressures. In some embodiments, suitable pressures within the reaction chamber may range from between about 10 mTorr and 10 Torr, or between about 20 mTorr and 8 Torr, or between about 50 mTorr and 5 Torr, or between about 100 mTorr and 2 Torr.

Various RF power levels may be employed to generate a plasma if used in operation (iii). In some embodiments, suitable RF power may range from between about 100 W and 10 kW, or between about 200 W and 6 kW, or between about 500 W, and 3 kW, or between about 1 kW and 2 kW.

Various film precursor flow rates may be employed in operation (i). In some embodiments, suitable flow rates may range from about or between 0.1 mL/min to 10 mL/min, or about or between 0.5 mL/min and 5 mL/min, or about or between 1 mL/min and 3 mL/min.

Various gas flow rates may be used in the various operations. In some embodiments, general gas flow rates may range from about or between 1 L/min and 20 L/min, or about or between 2 L/min and 10 L/min. For the optional inert purge steps in operations (ii) and (iv), an employed burst flow rate may range from about or between 20 L/min and 100 L/min, or about or between 40 L/min and 60 L/min.

Once again, in some embodiments, a pump-to-base step refers to pumping the reaction chamber to a base pressure by directly exposing it to one or more vacuum pumps. In some embodiments, the base pressure may typically be only a few milliTorr (e.g., between about 1 and 20 mTorr). Furthermore, as indicated above, a pump-to-base step may or may not be accompanied by an inert purge, and thus carrier gases may or may not be flowing when one or more valves open up the conductance path to the vacuum pump.

Also, once again, multiple ALD cycles may be repeated to build up stacks of conformal layers. In some embodiments, each layer may have substantially the same composition whereas in other embodiments, sequentially ALD deposited layers may have differing compositions, or in certain such embodiments, the composition may alternate from layer to layer or there may be a repeating sequence of layers having different compositions, as described above. Thus, depending on the embodiment, certain stack engineering concepts, such as those disclosed in the patent applications listed and incorporated by reference above (U.S. patent application Ser. Nos. 13/084,399, 13/242,084, and 13/224,240) may be used to modulate boron, phosphorus, or arsenic concentration in these films.

Detailed Description of Substrate Processing Apparatuses

The methods described herein may be performed with any suitable semiconductor substrate processing apparatus. A suitable apparatus includes hardware for accomplishing the process operations and a system controller having instructions for controlling process operations in accordance with the various channel doping methodologies disclosed herein. In some embodiments, the hardware may include one or more process stations included in a multi-station substrate processing tool, and a controller having (or having access to) machine-readable instructions for controlling process operations in accordance with the processing techniques disclosed herein.

Thus, in some embodiments, an apparatus suitable for depositing films of material on multiple semiconductor substrates may include a first set of one or more process stations each having a substrate holder contained in a processing chamber, a second set of one or more process stations each having a substrate holder contained in the processing chamber, one or more valves for controlling flow of film precursor to the process stations, and one or more valve-operated vacuum sources for removing film precursor from the volumes surrounding the process stations contained in the one or more processing chambers. And, such an apparatus may also include a controller having (or having access to) machine-readable instructions for operating the substrate loading device, the substrate transferring device, the one or more valves, and the vacuum source to deposit films of material onto the substrates.

Thus, in some embodiments, said instructions executed by the controller may include instructions for forming films on multiple substrates at multiple process stations contained in a processing chamber, wherein multiple layers of the film are formed on each substrate by a sequence of ALD cycles. Thus, in certain such embodiments, said instructions executed by the controller may include instructions for performing ALD operations (i) though (iv) as described above, and instructions for repeating ALD operations (i) through (iv) multiple times to form multiple layers of film on the multiple substrates at the multiple process stations of the substrate processing apparatus.

Accordingly, FIG. 1 schematically shows an embodiment of a substrate processing apparatus 100. For simplicity, processing apparatus 100 is depicted as a standalone process station having a process chamber body 102 for maintaining a low-pressure environment. However, it will be appreciated that a plurality of process stations may be included in a common process tool environment—e.g., within a common reaction chamber—as described herein. For example, FIG. 2 depicts an embodiment of a multi-station processing tool. Further, it will be appreciated that, in some embodiments, one or more hardware parameters of processing apparatus 100, including those discussed in detail above, may be adjusted programmatically by one or more system controllers.

Process station 100 fluidly communicates with reactant delivery system 101 for delivering process gases to a distribution showerhead 106. Reactant delivery system 101 includes a mixing vessel 104 for blending and/or conditioning process gases for delivery to showerhead 106. One or more mixing vessel inlet valves 120 may control introduction of process gases to mixing vessel 104.

Some reactants may be stored in liquid form prior to vaporization and subsequent delivery to the process chamber 102. The embodiment of FIG. 1 includes a vaporization point 103 for vaporizing liquid reactant to be supplied to mixing vessel 104. In some embodiments, vaporization point 103 may be a heated liquid injection module. In some embodiments, vaporization point 103 may be a heated vaporizer. The saturated reactant vapor produced from such modules/vaporizers may condense in downstream delivery piping when adequate controls are not in place (e.g., when no helium is used in vaporizing/atomizing the liquid reactant). Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 103 may be heat treated. In some examples, mixing vessel 104 may also be heat treated. In one non-limiting example, piping downstream of vaporization point 103 has an increasing temperature profile extending from approximately 100° C. to approximately 150° C. at mixing vessel 104.

As mentioned, in some embodiments the vaporization point 103 may be a heated liquid injection module (“liquid injector” for short). Such a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 803. In one scenario, a liquid injector may be mounted directly to mixing vessel 804. In another scenario, a liquid injector may be mounted directly to showerhead 106.

In some embodiments, a liquid flow controller (LFC) upstream of vaporization point 103 may be provided for controlling a mass flow of liquid for vaporization and delivery to processing chamber 102. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 106 distributes process gases and/or reactants (e.g., film precursors) toward substrate 112 at the process station, the flow of which is controlled by one or more valves upstream from the showerhead (e.g., valves 120, 120A, 105). In the embodiment shown in FIG. 1, substrate 112 is located beneath showerhead 106, and is shown resting on a pedestal 108. It will be appreciated that showerhead 106 may have any suitable shape, and may have any suitable number and arrangement of ports for distributing processes gases to substrate 112.

In some embodiments, a microvolume 107 is located beneath showerhead 106. Performing an ALD process in a microvolume in the process station near the substrate rather than in the entire volume of a processing chamber may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters.

In some embodiments, pedestal 108 may be raised or lowered to expose substrate 112 to microvolume 107 and/or to vary a volume of microvolume 107. For example, in a substrate transfer phase, pedestal 108 may be lowered to allow substrate 112 to be loaded onto pedestal 108. During a deposition on substrate process phase, pedestal 108 may be raised to position substrate 112 within microvolume 107. In some embodiments, microvolume 107 may completely enclose substrate 112 as well as a portion of pedestal 108 to create a region of high flow impedance during a deposition process.

Optionally, pedestal 108 may be lowered and/or raised during portions the deposition process to modulate process pressure, reactant concentration, etc. within microvolume 107. In one scenario where processing chamber body 102 remains at a base pressure during the process, lowering pedestal 108 may allow microvolume 107 to be evacuated. Example ratios of microvolume to process chamber volume include, but are not limited to, volume ratios between 1:500 and 1:10. It will be appreciated that, in some embodiments, pedestal height may be adjusted programmatically by a suitable system controller.

In another scenario, adjusting a height of pedestal 108 may allow a plasma density to be varied during plasma activation and/or treatment cycles included, for example, in an ALD or CVD process. At the conclusion of a deposition process phase, pedestal 108 may be lowered during another substrate transfer phase to allow removal of substrate 112 from pedestal 108.

While the example microvolume variations described herein refer to a height-adjustable pedestal, it will be appreciated that, in some embodiments, a position of showerhead 806 may be adjusted relative to pedestal 108 to vary a volume of microvolume 107. Further, it will be appreciated that a vertical position of pedestal 108 and/or showerhead 106 may be varied by any suitable mechanism within the scope of the present disclosure. In some embodiments, pedestal 108 may include a rotational axis for rotating an orientation of substrate 112. It will be appreciated that, in some embodiments, one or more of these example adjustments may be performed programmatically by one or more suitable system controllers having machine-readable instructions for performing all or a subset of the foregoing operations.

Returning to the embodiment shown in FIG. 1, showerhead 106 and pedestal 108 electrically communicate with RF power supply 114 and matching network 116 for powering a plasma. In some embodiments, the plasma energy may be controlled (e.g., via a system controller having appropriate machine-readable instructions) by controlling one or more of a process station pressure, a gas concentration, an RF source power, an RF source frequency, and a plasma power pulse timing. For example, RF power supply 114 and matching network 116 may be operated at any suitable power to form a plasma having a desired composition of radical species. Examples of suitable powers are included above. Likewise, RF power supply 114 may provide RF power of any suitable frequency. In some embodiments, RF power supply 114 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy (OES) sensors. In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma activation phase may be included in a corresponding plasma activation recipe phase of a process recipe. In some cases, process recipe phases may be sequentially arranged, so that all instructions for a process phase are executed concurrently with that process phase. In some embodiments, instructions for setting one or more plasma parameters may be included in a recipe phase preceding a plasma process phase. For example, a first recipe phase may include instructions for setting a flow rate of an inert (e.g., helium) and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations described herein, much shorter plasma strikes may be applied during a processing cycle. These may be on the order of 50 milliseconds to 1 second, with 0.25 seconds being a specific example. Such short RF plasma strikes require quick stabilization of the plasma. To accomplish this, the plasma generator may be configured such that the impedance match is preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with ALD cycles.

In some embodiments, pedestal 108 may be temperature controlled via heater 110. Further, in some embodiments, pressure control for processing apparatus 100 may be provided by one or more valve-operated vacuum sources such as butterfly valve 118. As shown in the embodiment of FIG. 1, butterfly valve 118 throttles a vacuum provided by a downstream vacuum pump (not shown). However, in some embodiments, pressure control of processing apparatus 100 may also be adjusted by varying a flow rate of one or more gases introduced to processing chamber 102. In some embodiments, the one or more valve-operated vacuum sources—such as butterfly valve 118—may be used for removing film precursor from the volumes surrounding the process stations during the appropriate ALD operational phases.

As described above, one or more process stations may be included in a multi-station substrate processing tool. FIG. 2 schematically illustrates an example of a multi-station processing tool 200 which includes a plurality of process stations 201, 202, 203, 204 in a common low-pressure processing chamber 214. By maintaining each station in a low-pressure environment, defects caused by vacuum breaks between film deposition processes may be avoided.

As shown in FIG. 2, the multi-station processing tool 200 has a substrate loading port 220, and a substrate handler robot 226 configured to move substrates from a cassette loaded from a pod 228, through atmospheric port 220, into the processing chamber 214, and finally onto a process station. Specifically, in this case, the substrate handler robot 226 loads substrates at process stations 201 and 202, and a substrate transferring device, in this case substrate carousel 290, transfers substrates between the various process stations 201, 202, 203, and 204. In the embodiment shown in FIG. 2, the substrate loading device is depicted as substrate handler robot 226 having 2 arms for substrate manipulation, and so, as depicted, it could load substrates at both stations 201 and 202 (perhaps simultaneously, or perhaps sequentially). Then, after loading at stations 201 and 202, the substrate transferring device, carousel 290 depicted in FIG. 2, can do a 180 degree rotation (about its central axis, which is substantially perpendicular to the plane of the substrates (coming out of the page), and substantially equidistant between the substrates) to transfer the two substrates from stations 201 and 202 to stations 203 and 204. At this point, handler robot 226 can load 2 new substrates at stations 201 and 202, completing the loading process. To unload, these steps can be reversed, except that if multiple sets of 4 wafers are to be processed, each unloading of 2 substrates by handler robot 226 would be accompanied by the loading of 2 new substrates prior to rotating the transferring carousel 290 by 180 degrees. Analogously, a one-armed handler robot configured to place substrates at just 1 station, say 201, would be used in a 4 step load process accompanied by 4 rotations of carousel 290 by 90 degrees to load substrates at all 4 stations.

The depicted processing chamber 214 shown in FIG. 2 provides four process stations, 201, 202, 203, and 204. Each station has a heated pedestal (shown at 218 for process station 901) and gas line inlets. It will be appreciated that in some embodiments, each process station may have different or multiple purposes. For example, in some embodiments, a process station may be switchable between an ALD process mode and a CVD process mode. Additionally or alternatively, in some embodiments, processing chamber 214 may include one or more matched pairs of ALD/CVD process stations. While the depicted processing chamber 214 comprises 4 process stations, it will be understood that a processing chamber according to the present disclosure may have any suitable number of stations. For example, in some embodiments, a processing chamber may have 1, or 2, or 3, or 4, or 5, or 6, or 7, or 8, or 9, or 10, or 11, or 12, or 13, or 14, or 15, or 16, or more process stations (or a set of embodiments may be described as having a number of process stations per reaction chamber within a range defined by any pair of the foregoing values, such as having 2 to 6 process stations per reaction chamber, or 4 to 8 process stations per reaction chamber, or 8 to 16 process stations per reaction chamber, etc.).

As indicated above, FIG. 2 depicts an embodiment of a substrate transferring device 290 for transferring substrates between process stations 201, 202, 203, and 204 within processing chamber 214. It will be appreciated that any suitable substrate transferring device may be employed. Non-limiting examples include wafer carousels and substrate handler robots.

Detailed Description of Actively Thermally Adjustable/Controlled Showerheads

As described above, various deposition processes and techniques disclosed herein employ a showerhead for dispensing film precursor which may have a thermal adjustment and/or control feature. A thermally adjustable and/or controlled showerhead may improve wafer-to-wafer and batch-to-batch uniformity of films deposited via ALD processes, but it may also increase throughput by eliminating non-processing delays, reducing particle generation through reduction of unwanted temperature variations, and, generally, may provide an additional valuable process parameter for fine-tuning film properties. ALD-formed film uniformity may improve from wafer-to-wafer within a batch because, through the use of a temperature controlled showerhead, temperature will vary less over a continuous batch of wafers—e.g., thus avoiding the scenario where the first wafers in a batch are deposited upon using a cold showerhead(s) whereas the last wafers in the batch are deposited upon using showerhead(s) having reached their equilibrium temperature. Likewise, by controlling all showerheads in a chamber to be at the same temperature, the film property uniformity between different sub-layers may be improved. Non-processing time—dummy deposition time just to heat the showerhead—may be eliminated, thus increasing throughput. Similarly, thermal cycling may be reduced because the showerhead temperature may be maintained while the station is idle or being cleaned, instead of allowing the showerhead to cool. An added benefit may be that the reduction in thermal cycling reduces the effect of different thermal expansion coefficients between chamber components (and coatings on the components) thereby reducing particle generation.

In some embodiments, a suitable temperature adjustable showerhead may be a chandelier-type showerhead, and furthermore, a design feature of such a showerhead may a thermal break at the interface between the showerhead face and body that allows for quick thermal response to the heat applied (additive heating and/or lowered heating duty cycle) or increased cooling. Such a quick response may be beneficial when an intervening plasma-based cleaning step (performed between ALD operations performed on sequential substrate batches) provides significant thermal energy to the showerhead and therefore the showerhead's temperature adjustment and/or control hardware must react quickly to the thermal variations (e.g. by cutting heat generation or be increasing coolant flow rate, etc.). A detailed description of certain examples of such showerheads is now provided.

Generally, a chandelier-type showerhead has a stem attached to the top of a chamber on one end and to the face plate on the other end, thus resembling a chandelier. A part of the stem may protrude from the chamber top to enable connection of gas lines and RF power. To control temperature, heat is added or removed based on the showerhead temperature. The showerhead temperature increases when the plasma is on, because charged particles collide with the showerhead to impart energy, and/or the applied RF energy is coupled to the showerhead. The showerhead temperature may also increase because external heat is intentionally added by, for example, as electrical energy from an electrical heater. The showerhead temperature decreases when cooler material enters the chamber, e.g., reactant gases at lower temperature or wafers at ambient temperature, when heat is removed by conduction, e.g., heat conduction through the showerhead stem material up to the chamber ceiling, and by radiation from the showerhead surfaces. Some of these thermal events occur as a part of normal chamber operation, and others may be used to control showerhead temperature.

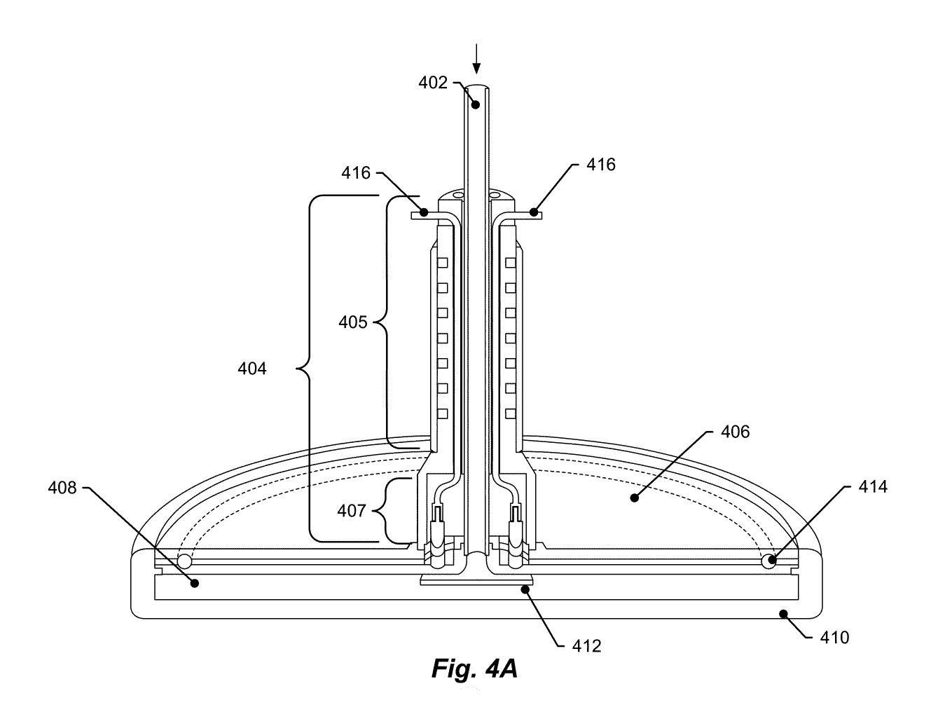

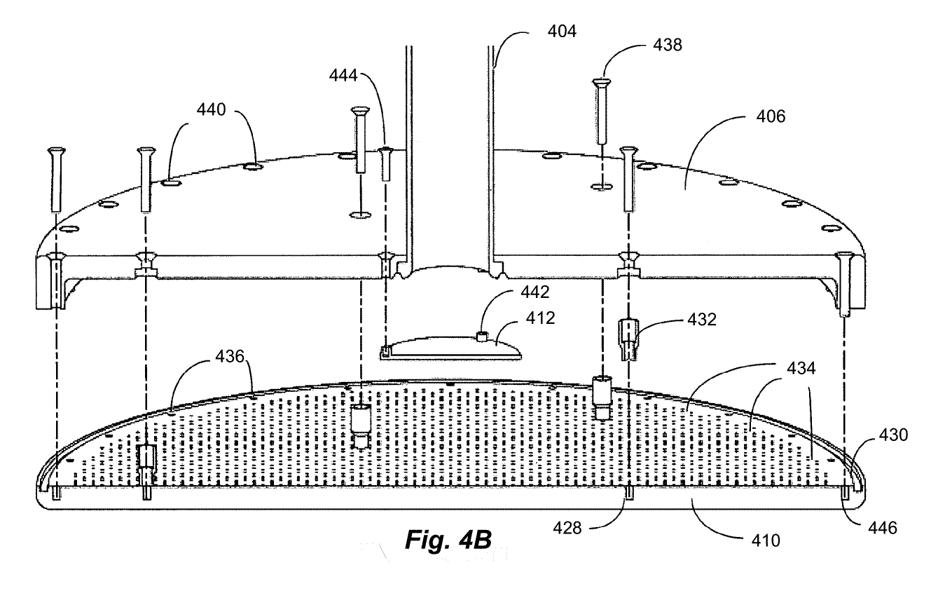

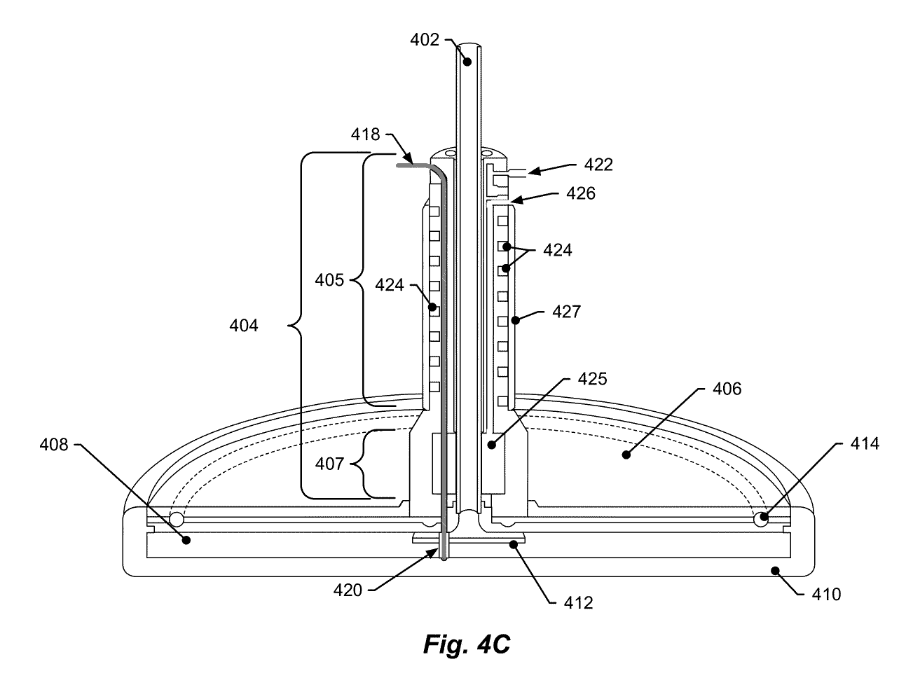

FIGS. 4A, 4B, and 4C are cross-section schematics of a showerhead in accordance with various embodiments of the present invention. Referring to FIG. 4A, the showerhead 400 includes a stem 404, a back plate 406, and a face plate 410. The stem 404 may be divided into an upper and a lower section, which may have different diameters. In one embodiment, the upper stem has a diameter of about 1.5 to 2 inches, preferably about 1.75 inches. The lower stem diameter is about 2 to 2.5 inches, preferably about 2.25 inches. The face plate diameter may be slightly larger and comparable or slightly larger than the wafer size, preferably about 100% to 125% of the wafer size. For example, for a 300 mm (12 inch) processing chamber the face plate diameter may be about 13 inches or about 15 inches. The face plate and back plate may each have a thickness of about 0.25 to 0.5 inches, or about 0.125 to 0.5 inches, or about 0.25-0.375 inches. The face plate may be made of an aluminum, anodized or coated aluminum, or other metal that is formulated to be high temperature, chemical and plasma resistant.

In one embodiment, the back plate is about 0.5 inches thick, and the face plate is about three eighths of an inch. Reactant gases are introduced through gas inlet channel 402 in the showerhead stem 404, flow past the back plate 406 and enter the manifold area 408 between the back plate 406 and the face plate 410. Referring to FIG. 4B, a baffle 412 distributes the gases evenly throughout the manifold area 408. The baffle 412 may be attached to the back plate 406 via threaded inserts or threaded holes 442 in the baffle plate and a number of screws 444. Volume of the manifold area is defined by the gap between the back plate and the face plate. The gap may be about 0.5 to 1 inch, preferably about 0.75 inch. To maintain uniform gas flow in the gap, the gap may be kept constant with a number of separator/spacers 432 positioned between the back plate and the face plate at various locations, e.g. 3, 6, or up to 10 locations. As shown, a screw 438 fastens the back plate 406 through separator/spacers 432, to the face plate at threaded blind holes 428. In other embodiments, variously shaped spacers or bushings with or without internal threads may be used. Although the screws shown enter the back plate and threads into the face plate, the reverse configuration may be used. For example, screws may be embedded in the face plate and enters a through hole in the back plate through a spacer. The screws may be fastened to the back plate with nuts.

The gases enter the processing area through perforations or holes (434) in the face plate 410 to cause a deposition on the surface of a wafer. The through holes may be machined, milled, or drilled. Each hole may be about 0.04 inch in diameter, or about 0.01 to 0.5 inches in diameter. Some holes may have different sizes. The number of holes may be 100-10,000, 2-5000, about 3-4000, or about 200-2000 holes. The holes may be distributed evenly throughout the face plate in various patterns, e.g., a honey comb pattern or increasingly larger circles. Depending on various factors including desired film uniformity, film profile and gas flow, the holes may have various patterns of non-even distribution, such as being more densely distributed in the middle of the face plate or more densely distributed at the edge of the face plate. In one embodiment, the holes may have a pattern of uniformly spaced circles with the holes placed increasingly apart further away from the center. Generally, various hole patterns and densities may be used.

In some cases, the face plate 410 is removably attached to the back plate 406 so that the perforation/hole configuration may be easily changed and the face plate cleaned. The back surface of the face plate 410 may include mating features to attach and detach from the back plate. As shown, the mating feature may be groove 430 and threaded blind holes 446. The groove 430 may mate onto corresponding lip on the back plate. Screw holes 440 on the back plate or face plate are positioned circumferentially and match holes 446. Screws attach the back plate and face plate together. The number of circumferentially positioned screws may be more than 4, more than 10, about 24, or up to about 50. Other mating features for the back plate and the face plate may be used. For example, other fastening mechanisms may include straps or clips or a simple friction based engagement may be used where the dimensions of the face plate closely matches those of a corresponding receptacle in the back plate. As shown in FIG. 4A, the face plate may include a circumferential sidewall having a ledge. The back plate may be positioned on the ledge and be attached with screws. In one embodiment, an interlocking jaw mechanism is used where specially machined notches on the circumferential sidewall edge of the back plate or face plate mate with teeth on the counterpart. The back plate and the face plate may become attached by friction when the showerhead is heated and the teeth and notches expand. Such mechanism involving non-moving parts may be preferable to screws which must be threaded and may strip and release particles. Yet another possible mechanism involves threads on a circumferential sidewall of the face plate or the back plate that can screw into a respective counterpart. Regardless of the mating feature and fastening mechanism, the back plate and face plate are attached in such way to maintain good electrical and thermal contact between them.

During operation, a showerhead face plate experiences stressful conditions in the chamber. For example, thermal stress from the temperature changes up to very high temperatures, e.g., above 300° C., can warp the back plate or the face plate and degrade the material. Plasma during operation can erode surface material, causing particles and weak spots. Reactants can also corrode the face plate in a chemical attack, e.g. fluorine gas. Unwanted deposition of reaction products or by products can clog the gas flow holes affecting process performance, cause particles when a film builds up on the surface, or affect plasma properties in the case of aluminum fluoride. Cumulatively, these events may affect process performance in terms of particles, uniformity, and plasma performance. The ability to clean or replace just the face plate is cost effective without having to replace the entire showerhead assembly.

Referring again to FIG. 4A, a heater 414 in the form of an electrically resistive element may be thermally attached to the back plate 406 as shown in the figure. In some embodiments, the heater 414 may be embedded in the back plate 406. The heater may be attached by a vacuum brazing process. The heater in the form of electrically resistive element 414 is controlled by heater wires 416 that are connected to the electrically resistive element through the stem. Because the showerhead is subjected to high RF energy during chamber operation, all or part of the electrically resistive element may be insulated and isolated from the RF. The RF isolation may be accomplished through an EMI/RFI filter or any other commercially available RF isolation device.

FIG. 4C shows a slightly different cross section of the showerhead to emphasize other elements. In this figure, a temperature sensor 418 is shown in thermal contact with face plate 410 to measure the temperature of the showerhead, specifically at the showerhead's face plate. In some embodiments, such as that shown in FIG. 4C, the temperature sensor 418 may be a thermocouple. Here the thermocouple/temperature sensor 418 is connected from the upper stem through a standoff 420 between the back plate 406 and face plate 410. At the face plate 410, the thermocouple may contact the face plate material in a sensor contact hole. Similar to the heater wire and elements, the thermocouple is also insulated and isolated from the RF. The RF isolation may be accomplished through an RF trap at a frequency and an RF filter at another frequency. In other embodiments, other types of temperature sensing devices may be used to measure the temperature of the face plate. Particularly, a non-contact temperature sensor may be used. Examples include pyrometry, fluorescence-based thermometry and infrared thermometry.

The temperature controlled showerhead enhances heat removal by conduction, convection and radiation. Heat is conducted away through the showerhead stem itself, which is connected to a chamber top. The stem diameter may be designed to maximize conductive heat loss to the chamber top. Heat may also be removed by convection through cooling fluids flowing in a cooling fluid conduit in the stem 404. The embodiment in FIG. 4C includes a cooling fluid inlet 422, into which cooling fluids, e.g., clean dry air (CDA), argon, helium, nitrogen, hydrogen, or a mixture of these, may be flowed. The fluid may follow a helical path down the stem. The helical path is shown in FIG. 4C through conduits 424 of the convective cooling fluid passageway. The cooling fluid may exit the stem through one or more cooling fluid exit channels 426. In one embodiment, two cooling fluid exit channels are provided. Although the example here uses a helical passageway, one skilled in the art may design another tortuous passageway to effectively transfer heat from the showerhead to the cooling fluid.

The fluid cooling conduits (or channels) may be designed so that the exiting fluid is completely heated up to the temperature of the showerhead stem. Because the faceplate temperature and stem temperature are correlated, it is possible to deduce the faceplate temperature by measuring the temperature of the exiting fluid. The exiting fluid temperature may be measured away from the electromagnetic interference caused by the RF. This design may avoid the use of a thermocouple inside the showerhead and its associated RF filtering circuitry.

In another scenario, the cooling fluid may further be modulated to control the amount of cooling. A feedback loop based on the exiting fluid temperature may increase or decrease the flow to change the amount of cooling. This cooling may be in addition to or instead of heat on the back plate. For less demanding applications, the cooing alone may be used to control the showerhead temperature; and, the heater elements and RF isolation devices may be omitted. For more demanding application, the modulation of cooling fluid is an additional parameter to control the showerhead temperature.

In addition to conduction and convection, heat may radiate away from the showerhead from the back plate. To improve radiative cooling, the external surface of the back plate may be coated with a high emissivity material. For example, the coating may be anodized aluminum. The radiation may be absorbed by the top of the chamber. The chamber top may also be treated with a high emissivity material to increase radiative heat transfer. The inside surface of the chamber top may be coated with anodized aluminum. The chamber top may be cooled independently, e.g., with cooling water lines.

The conductive and radiative heat removal keeps the showerhead at low enough temperatures whereby the electrical heater can accurately heat it back. Without the heat removal, the showerhead temperature would remain high and uncontrollable. The heat removal creates headroom for temperature control. In one embodiment, the heat removal keeps the showerhead temperature below about 200° C. The heater may be a simple coil around the perimeter of the back plate because most of the heat transfer between the face and back plate is around the perimeter. Better thermal contact between the showerhead and back plate also improves temperature control because conductive heat transfer, and thus heat loss through the stem, is enhanced.

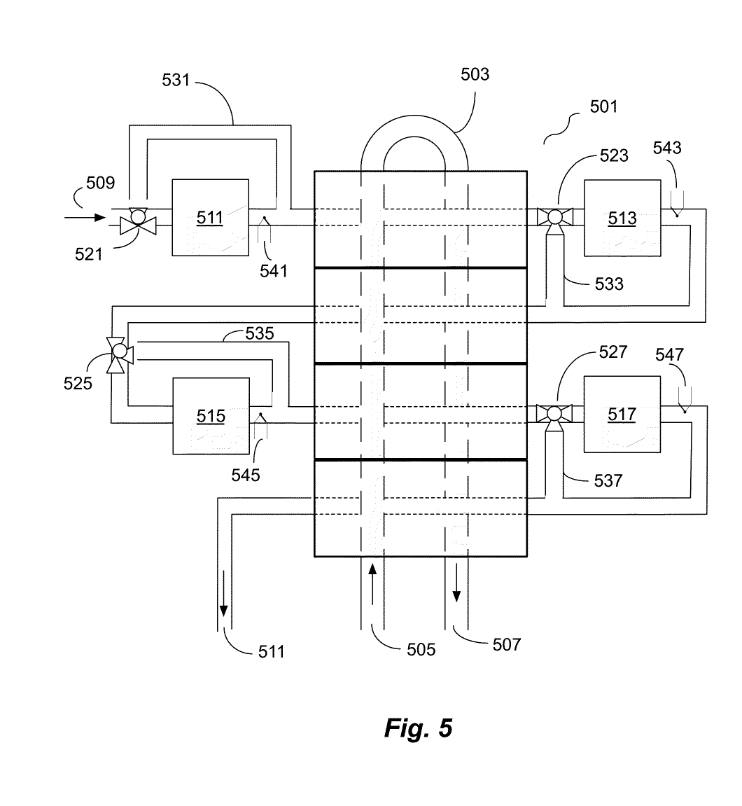

In some embodiments, a cooling system may be connected to one or more showerhead stems like those shown in FIG. 4 and may cool the convective cooling fluid that flows through the showerhead stems. The cooling system includes a liquid cooled heat exchanger and connections to the showerheads. FIG. 5 is schematic of a cooling system in accordance with one embodiment of the present invention. In this embodiment, a heat exchanger 501 is connected to four showerheads 511, 513, 515, and 517. The convective cooling fluid flows serially through each showerhead and a compartment of the heat exchanger 501. Note, however, that depending on the embodiment, if one were to schematically replace the four showerheads 511, 513, 515, and 517 with four pedestal-type substrate holders, the foregoing cooling system could also serve as an implementation of a substrate holder cooling system, presuming that suitable adjustments to coolant fluid flow rates, heat exchanger capacity, etc. are made to adjust for difference in the total thermal load corresponding to 4 showerheads versus 4 substrate holders.

In any event, using the example of such a cooling system implemented to actively cool showerheads as schematically indicated by showerheads 511, 513, 515, and 517 in FIG. 5, the convective cooling fluid enters the system at inlet 509 where it enters the first showerhead stem. After flowing through one showerhead, the convective cooling fluid is cooled by a liquid coolant in the heat exchanger before flowing through the next showerhead. After the last cooling through a last compartment in the heat exchanger, the convective cooling fluid is exhausted from the cooling system at outlet 511. The convective cooling fluid may be clean dry air (CDA), argon, helium, nitrogen, hydrogen, or a combination of one or more of these. For the case of a thermally adjusted/controlled pedestal, chilled water may be used. In one embodiment, the convective cooling fluid is facilities provided CDA at a facilities pressure. A different flow rate may be required for different facilities pressures. For example, at facilities pressure of 80 psi, 100 standard liters per minute (slm) of CDA may be used. The exhaust may be at about or slightly above ambient temperature and pressure. Although an open system is shown where the convective cooling fluid does not return to the system, the concept of serial flow through the showerhead and intermediate cooling through one heat exchanger also may be implemented with a closed system.

In some embodiments, exiting cooling fluid temperature from the showerhead is measured and used to determine the showerhead temperature. Temperature sensor 541, 543, 545, and 547 may be thermally coupled to the exiting cooling fluid and yet be outside the range of RF interference. This configuration would eliminate the need for an RF filtering device. As discussed above, the convective cooling passageways may be designed so that the exiting cooling fluid temperature is the same as that of the showerhead stem. One skilled in the art would then be able to devise algorithms to correlate measured exiting fluid temperatures to showerhead temperatures knowing thermal properties of the various components.

In certain embodiments, the showerhead may not include a heater attached to the back plate. The showerhead temperature increases during processing, preheating, and remote plasma cleaning. In these embodiments, active cooling from the cooing fluid may be used to control showerhead temperature. Control valves 521, 523, 525, and 527 controls the flow of cooling fluids to the showerhead based on input from the controller. The cooling fluid either flows to the showerhead stem or is diverted in a by-pass loop 531, 533, 535, or 537. More or less cooling may be accomplished based on the flow of cooling fluids to the showerhead. An active cooling only design may be appropriate in certain less demanding applications where the range of acceptable showerhead temperatures is larger, or in embodiments wherein active showerhead cooling is employed in order to stabilize showerhead temperature and minimize or prevent temperature fluctuations due to remote plasma clean. In these embodiments, the showerhead temperature it may be feasible to determined showerhead temperature based on the exit cooling fluid temperature or be measured at the showerhead through a contact thermocouple or through a non-contact thermal sensing means.

Note that while four showerheads and four compartments are shown in FIG. 5, cooling systems may be designed with another number of showerheads and compartments. Such a cooling system may also be configured to provide cooling to 4 substrate holders, depending on the embodiment. In some embodiments, the cooling system may serve to cool the showerheads for more than one semiconductor processing chamber or tool. For example, if each semiconductor processing tool has one multi-station chamber with four stations each, a cooling system having 8 compartments connecting to 8 showerheads may be designed to serve 2 tools. Some semiconductor processing tools may have more than one multistation chamber. In that case a cooling system may be designed to serve all the showerheads in more than one chamber on a single tool. If a four compartment heat exchanger is used on a tool having more than one four-station chamber, more than one heat exchanger per tool may be used.

In some cases one or more of the showerheads may be bypassed for convective cooling fluid flow altogether. Thus each showerhead connection may also include a bypass loop with corresponding valves. For certain processes, not every station may be configured to deposit material onto the wafer or require a temperature controlled showerhead. In that case the bypass loop may be used at station 4.

The liquid coolant for the heat exchanger 501 enters the system at inlet 505 and follows a coolant path 503 before it exits the system at outlet 507. Although only one loop is shown for coolant path 503, the coolant path may consist of many loops depending on the diameter of the coolant path, heat transfer required, the coolant temperature at the inlet, and any coolant temperature requirements at the exit. The liquid coolant may be water or any other type of known liquid coolant, e.g., Freon. In one embodiment, the liquid coolant is facilities delivered water. After exiting the heat exchanger, the liquid coolant may or may not be treated further before being released, for example, into the drain. For example, the facilities delivered water as the liquid coolant may be exhausted directly. However, if other liquid coolant is used, the coolant may be compressed and recirculated back into the heat exchanger, creating a closed-loop coolant system.

Different designs of the heat exchanger 501 may be utilized. FIG. 5 shows a cross-flow heat exchanger where the currents run approximately perpendicular to each other. However, counter-flow or parallel-flow heat exchangers may be used. One skilled in the art would be able to design a heat exchanger with enough surface area to cause desired heat transfer. In certain embodiments, the heat exchanger 501 may be a cast metal enclosing the liquid coolant and convective cooling fluid piping. The metal may be aluminum or other metal with desired heat transfer characteristics. The cast metal design allows for a compact heat exchanger with little footprint or space requirement.

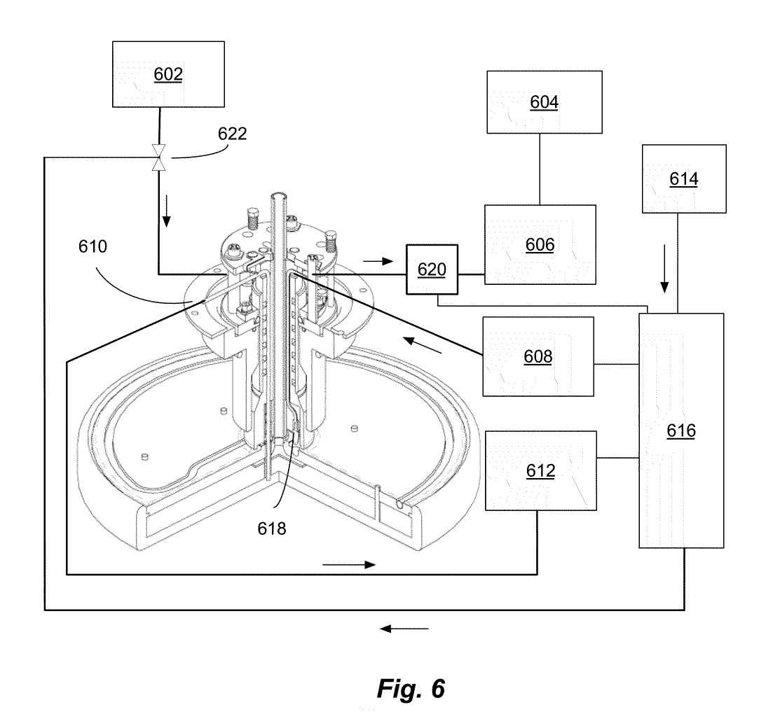

The showerhead—and, for that matter, a temperature adjustable/controllable substrate holder as well—may be linked to a temperature control system. A showerhead temperature control system is illustrated schematically in FIG. 6, which depicts the major components of the temperature control system, such as a cooling subsystem, as it relates to one showerhead. Note that showerhead graphic in this figure includes the attachment parts to the chamber top. Convective cooling fluid flows from component 602 into the showerhead stem where it is heated in the process of cooling the showerhead, and exits to the heat exchanger 606. In some embodiments, the cooling fluid flow into the showerhead is modulated by a control valve or other flow modulator 622. By modulating the flow, the cooling provided by the cooling fluid may be increased or decreased.

From the heat exchanger 606, as discussed above, the convective cooling fluid may be flowed to another component, such as 604. If the showerhead is configured as the first station in a chamber, then component 602 may be the facilities air and component 604 may be another showerhead, such as station showerhead. If the showerhead is not configured as the first station, then component 602 and 606 may be the same component, the liquid cooled heat exchanger as discussed above. Note that this cooling loop may not have a feed back loop where more or less cooling may be adjusted. The simple design merely cools the showerhead enough such that the electric heater 618 may accurately heat the showerhead to a certain temperature.

Thermocouple 610 is in physical contact with the face plate, as discussed above. Thermocouple 610 is connected to a RF isolation device 612 to remove the effect of RF applied on the showerhead as an electrode from the thermocouple signal. Typically, the RF applied in a PECVD has two frequency components, a high frequency (e.g., 13.56 MHz) trap and a low frequency (e.g., 400 kHz). The RF isolation device may include one or more filters. In one embodiment, the RF isolation device includes a high frequency and a low frequency filter. Without RF isolation, it is believed that the thermocouple measurement would not be useful because the RF interference would be too great.

Referring again to FIG. 6. the heater element 618 is connected to its RF isolation device 608. RF isolation device 608 may be an RF filter or other available device to isolate the heater electrical signals from the effects of the RF applied. The temperature controller 616 reads the temperature information from the thermocouple 610 through the isolation device 612, and adjusts input to the heater 618 through the RF isolation device 608 in a feed back loop.

In another embodiment, the exit cooling fluid temperature may be measured by a temperature sensing device 620 that is outside of the range of RF interference. In this embodiment, no RF filter is required for the temperature sensing device 620. The controller may correlate the exit cooling fluid temperature to a showerhead temperature.

The temperature controller 616 may also take feed forward information from component 614. The feed forward information may be that the time period until the plasma turns on. In some cases the feed forward information may also include other predictable events that affect the showerhead temperature such as wafer processing with cold wafers, gas flow into the showerhead. The controller may increase the heater input in anticipation of a cooling event, e.g., chamber purge, or decrease the heater input in anticipation of a heating event, e.g., plasma “on.” The controller may also increase the cooling by increasing cooling fluid flow in anticipation of a heating event or decrease the cooling by decreasing cooling fluid flow in anticipation of a cooling event.

Various combinations of the input and output components may be used in different controlling schemes. For example, in some embodiments, active cooling (modulating cooling fluid flow) may be used with active heating (heater in the back plate) to accurately control showerhead temperature. Depending on the embodiment, showerhead temperature may be measured directly from a thermocouple attached to the face plate, or determined indirectly from the exiting cooling fluid temperature. In some embodiments, only active cooling or only active heating may be included in the control system. Still other inputs may be included, such as temperature sensing of the cooling fluid at the inlet to accurately determine the heat removed from the showerhead. In certain embodiments, the temperature controller may be integrated with the system controller. Thus, in some embodiments, an apparatus for forming films on substrates via ALD processes implementing the foregoing thermal adjustment/control techniques/operations with respect to showerheads may include a showerhead having an electrically resistive element for heating the showerhead and a temperature sensor, as well as one or more controllers having instructions for controlling current flow through the electrically resistive element in response to signals from the temperature sensor. Such controllers for controlling these and other operations of such an apparatus will be described in greater detail below.

It is noted that a thermal adjustment/control system analogous to the foregoing may also be used for thermal adjustment/control of a substrate holder having a thermal adjustment and/or control feature such as, for example, a substrate holder having conduits for flowing a cooling fluid, as described below. In certain embodiments, such a thermal adjustment/control system may control, in tandem, both a showerhead and substrate holder each having thermal adjustment and/or control features, in order to effectuate the ALD processes described above.

Detailed Description of Actively Thermally Adjustable/Controlled Substrate Holders

As indicated above, a substrate holder having a thermal adjustment and/or control feature may be used in combination with a showerhead having a thermal adjustment and/or control feature in order to implement ALD processes as described above for reducing pre-/post-plasma clean dep variation. In some embodiments, the substrate holder may have a pedestal-shaped configuration, and in some embodiments it may be formed with one or more internal heating elements and one or more internal cooling elements.

One example of a pedestal-shaped substrate holder having separate internal heating and cooling elements is schematically illustrated in FIGS. 7A-7C. In this sort of design, a pedestal insert 750 (see FIG. 7C) is used to provide the active cooling, and heating is provided by heating element 770—in this case an electrically resistive coil heating element—formed in the disc-shaped substrate support.

FIG. 7A shows this example substrate holder 700 from an external perspective view. The substrate holder 700 has a disc-shaped substrate support having an upper contact face 710 for contacting the bottom side of a substrate to be processed, and a lower face 720 which connects to the substrate holder's central support column 730 which supports it. The figure also shows a disc-shaped mounting flange 740 which circles around the central support column 730 of the pedestal and facilitates chamber installation of the pedestal. It is noted that the upper 710 and lower 720 faces of the disc shaped support create a relatively low-profile so that the substrate holder's heat capacity and/or thermal inertia is reduced thus enabling internal temperature control mechanisms to more rapidly achieve their desired effect.

FIG. 7B provides a cut-away perspective view showing pedestal insert 750 (for active cooling) built into central support column 730, and FIG. 7C provides a close-up perspective view of this pedestal insert 750 which consists of cooling block 755 along with cooling fluid conduits 760. It is seen from FIGS. 7B-7C that the cooling block 755 and conduits 760 fit inside central support column 730 in a cylindrical space oriented along its central axis. The cooling block 755 may be made from a thermally-conductive material such as a metal, e.g., aluminum. Thus, when cooling fluid is flowed through cooling conduits 760, the pedestal may be actively cooled. The rate of flow of cooling fluid (“coolant”) through cooling conduits 760, and the thermal properties of the particular cooling fluid chosen, may also affect the extent to which the pedestal is actively cooled.

In addition, it is noted that the substrate holder's thermal response is effected by the thermal conductivity of the central support column 730, including pedestal insert 750, and their physical connection to the disc-shaped support (defined by upper and lower faces 710 and 720). For instance, cooling conduits 760 define a region within the central support column 730 which is mostly space/air/etc. having a low thermal conductivity. Thus, the volume ratio of this cylindrical space filled by cooling block 755 may be used to adjust the thermal conductivity of the support column 730 as well. It is seen in FIGS. 7B-C, for example, that this volume ratio is about 1:4 (cooling block:space). Such thermal conductivity adjustment of the support column may change the overall thermal sensitivity of the substrate holder. Moreover, it is also noted that, depending on the embodiment, the radius of the cooling block 755 may be used to effect differential center to edge (centrosymmetric) heating and/or cooling. Thus, dep control plus specific center to edge temperature profile may be combined, in certain embodiments.

Another example of a pedestal-shaped substrate holder having an internal cooling element is schematically illustrated in FIGS. 7D-7E. FIGS. 7D and 7E display cross-section and cut-away views, respectively, of this substrate holder's internal heating element 770 and cooling element 780. The cross-section view of FIG. 7D shows that in this embodiment the heating element 770 is located in a plane above the plane of the cooling element 780. In this particular embodiment, the heating element 770 is an electrically resistive coil (as in the embodiment shown in FIGS. 7A-7B) and the cooling elements 780 are cooling fluid conduits, both formed in the disc-shaped substrate support. It is noted, however, that in other embodiments the heating elements may also be fluid conduits, in this case for the flow of a heating fluid.

The cut-away view of FIG. 7E illustrates that within each plane, the heating and cooling elements are designed so that some portion of their structure is within reasonably close spatial proximity to—and thus in reasonably good thermal contact with—the entire upper contact face 710 of the substrate holder. Of course, many intricate designs for these elements may be envisioned which ensure that some portion of said structures are within reasonably close proximity to every region of the substrate holder's upper contact face 710. For instance, the heating and cooling elements may be designed such that their structures are vertically interleaved/interwoven so that a choice of which element occupies a plane nearest to the substrate need not be made. Various choices for cooling fluid (coolant) and heating fluid (when the heating element employs a heating fluid) are possible. As used herein, fluid refers to both liquids and gases. Thus, heating fluids may be heated inert gases, for example, and cooling fluids may be coolants such as Freon, or chilled water, or Galden, for example. (‘Galden’ is a family of heat transfer fluids commercially available from Solvay Specialty Polymers.) The cross-section view of FIG. 7D also illustrates that the cooling fluid conduits within the disc-shaped substrate support are fed with cooling fluid from conduits for flowing the fluid up and down the central support column 730.

While designs having separate fluid conduits for heating and cooling fluids may in principle provide very flexible temperature control functionality, in scenarios where either heating or cooling are individual deemed most important, or solely important, a single fluid flow conduit may be employed creating a slightly more simple design. Such a single conduit design may also be sufficient if the switch from needing active heating to active cooling is sufficiently infrequent, or if the switch from active heating to active cooling may be modulated by adjusting the temperature of the single flowing fluid itself. Single conduit designs may also be a good choice if another mechanism is chosen for active heating such as employing one or more electrically resistive coil heating elements as done in the embodiment shown in FIGS. 7D-7E. This may provide distributed heating of the entire upper contact face 710.

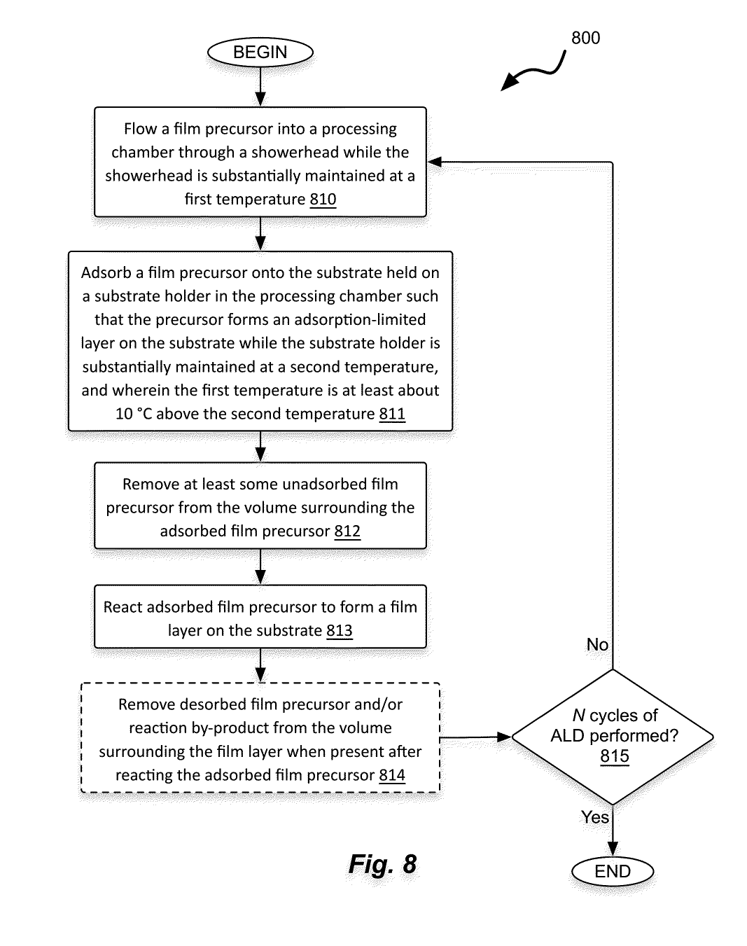

As mentioned above, a temperature control system, similar to that described above with respect to FIG. 6 for adjusting and/or controlling showerhead temperature, may also be used to adjust and/or control substrate holder temperature, for example, through the use of the heating and cooling elements shown in FIGS. 7D-7E and optionally one or more temperature sensors. (Depending on the embodiment, temperature sensors may be of the types described above with respect to thermally adjustable/controlled showerheads.) Moreover, such a temperature control system may adjust and/or control temperatures in both a showerhead and substrate support in tandem as may be done in the context of the various ALD methodologies for reducing deposition variation described above. Likewise, it is noted that a fluid cooling system, similar to that described above with respect to FIG. 5 for adjusting and/or controlling showerhead temperature, may be used to cool and modulate the temperature of the cooling fluid flowing through conduits 780 in FIGS. 7D-8E through the use of a liquid-cooled heat exchanger similar to 501 in FIG. 5. In such an embodiment, cold cooling fluid may be received from a heat exchanger into cooling fluid conduit 880 where it will have its cooling effect on the pedestal substrate holder and then subsequently after it exits conduit 780 may be routed back to the heat exchanger. Thus, in some embodiments, an apparatus for forming films on substrates via ALD processes implementing the foregoing thermal adjustment/control techniques/operations with respect to showerheads and substrate holders may include a pedestal substrate holder having internal cooling conduits and a temperature sensor, as well as one or more controllers having instructions for controlling flow of fluid through the cooling conduits in response to signals from the temperature sensor. Such controllers for controlling these and other operations of such an apparatus are described in greater detail below.

### Example Process Flow

FIG. 8 provides an example flowchart illustrating a sequence of ALD operations consistent with the techniques disclosed herein for improving ALD film consistency through active thermal adjustment and/or control of showerhead and substrate holders.

A shown in the figure, an ALD process for forming a single layer of film on a substrate may begin with an operation 810 of flowing a film precursor into a processing chamber through a showerhead while the showerhead is substantially maintained at a first temperature. Then, in operation 811, said film precursor is adsorbed onto the substrate while held on a substrate holder in the processing chamber such that the precursor forms an adsorption-limited layer on the substrate while the substrate holder is substantially maintained at a second temperature. As indicated in FIG. 8, in this particular example, the first temperature is at least about 10° C. above the second temperature. The absorption operation is followed by an operation 812 of removing at least some unadsorbed film precursor from the volume surrounding the adsorbed precursor, and thereafter, in an operation 813, the adsorbed film precursor is reacted to form a film layer on the substrate. Finally, in some embodiments (as indicated by the dashed-line-drawn box in FIG. 8) and depending on the chemistry of the film-forming reaction, operation 813 may be followed by an operation 814 to remove desorbed film precursor and/or reaction byproduct from the volume surrounding the film layer when present after reacting the adsorbed precursor in operation 813.

The foregoing sequence of operations 810 through 814 represent a single ALD cycle resulting in the formation of a single layer of film. However, since a single layer of film formed via ALD is typically very thin—often it is only a single molecule thick—multiple ALD cycles are repeated in sequence to build up a film of appreciable thickness. Thus, referring again to FIG. 8, if it is desired that a film of say N layers be deposited (or, equivalently, one might say N layers of film), then multiple ALD cycles (operations 810 to 814) are repeated in sequence and after each ALD cycle concludes with operation 814, in operation 815, it is determined whether N cycles of ALD have been performed. Then, if N cycles have been performed, the film-forming operations conclude, whereas if not, the process sequence returns to operation 811 to begin another cycle of ALD. In so doing, a conformal film of the desired thickness may be deposited.

System Controllers

FIG. 2 also depicts an embodiment of a system controller 250 employed to control process conditions and hardware states of process tool 200 and its process stations. System controller 250 may include one or more memory devices 256, one or more mass storage devices 254, and one or more processors 252. Processor 252 may include one or more CPUs, ASICs, general-purpose computer(s) and/or specific purpose computer(s), one or more analog and/or digital input/output connection(s), one or more stepper motor controller board(s), etc.

In some embodiments, system controller 250 controls some or all of the operations of process tool 200 including the operations of its individual process stations. System controller 250 may execute machine-readable system control instructions 258 on processor 252—the system control instructions 258, in some embodiments, loaded into memory device 256 from mass storage device 254. System control instructions 258 may include instructions for controlling the timing, mixture of gaseous and liquid reactants, chamber and/or station pressure, chamber and/or station temperature, wafer temperature, target power levels, RF power levels, RF exposure time, substrate pedestal, chuck, and/or susceptor position, and other parameters of a particular process performed by process tool 200. These processes may include various types of processes including, but not limited to, processes related to deposition of film on substrates. System control instructions 258 may be configured in any suitable way. For example, various process tool component subroutines or control objects may be written to control operation of the process tool components necessary to carry out various process tool processes. System control instructions 258 may be coded in any suitable computer readable programming language. In some embodiments, system control instructions 258 are implemented in software, in other embodiments, the instructions may be implemented in hardware—for example, hard-coded as logic in an ASIC (application specific integrated circuit), or, in other embodiments, implemented as a combination of software and hardware.

In some embodiments, system control software 258 may include input/output control (IOC) sequencing instructions for controlling the various parameters described above. For example, each phase of a deposition process or processes may include one or more instructions for execution by system controller 250. The instructions for setting process conditions for a film deposition process phase, for example, may be included in a corresponding deposition recipe phase. In some embodiments, the recipe phases may be sequentially arranged, so that all instructions for a process phase are executed concurrently with that process phase.

Other computer-readable instructions and/or programs stored on mass storage device 254 and/or memory device 256 associated with system controller 250 may be employed in some embodiments. Examples of programs or sections of programs include a substrate positioning program, a process gas control program, a pressure control program, a heater control program, and a plasma control program.

A substrate positioning program may include instructions for process tool components that are used to load the substrate onto pedestal 218 and to control the spacing between the substrate and other parts of process tool 200. The positioning program may include instructions for appropriately moving substrates in and out of the reaction chamber as necessary to deposit film on the substrates.

A process gas control program may include instructions for controlling gas composition and flow rates and optionally for flowing gas into the volumes surrounding one or more process stations prior to deposition in order to stabilize the pressure in these volumes. In some embodiments, the process gas control program may include instructions for introducing certain gases into the volume(s) surrounding the one or more process stations within a processing chamber during film deposition on substrates. The process gas control program may also include instructions to deliver these gases at the same rates, for the same durations, or at different rates and/or for different durations depending on the composition of the film being deposited. The process gas control program may also include instructions for atomizing/vaporizing a liquid reactant in the presence of helium or some other carrier gas in a heated injection module.

A pressure control program may include instructions for controlling the pressure in the process station by regulating, for example, a throttle valve in the exhaust system of the process station, a gas flow into the process station, etc. The pressure control program may include instructions for maintaining the same or different pressures during deposition of the various film types on the substrates.

A heater control program may include instructions for controlling the current to a heating unit that is used to heat the substrates. Alternatively or in addition, the heater control program may control delivery of a heat transfer gas (such as helium) to the substrate. The heater control program may include instructions for maintaining the same or different temperatures in the reaction chamber and/or volumes surrounding the process stations during deposition of the various film types on the substrates.

A plasma control program may include instructions for setting RF power levels, frequencies, and exposure times in one or more process stations in accordance with the embodiments herein. In some embodiments, the plasma control program may include instructions for using the same or different RF power levels and/or frequencies and/or exposure times during film deposition on the substrates.

In some embodiments, there may be a user interface associated with system controller 250. The user interface may include a display screen, graphical software displays of the apparatus and/or process conditions, and user input devices such as pointing devices, keyboards, touch screens, microphones, etc.

In some embodiments, parameters adjusted by system controller 250 may relate to process conditions. Non-limiting examples include process gas compositions and flow rates, temperatures (e.g., substrate holder and showerhead temperatures), pressures, plasma conditions (such as RF bias power levels and exposure times), etc. These parameters may be provided to the user in the form of a recipe, which may be entered utilizing the user interface.

Signals for monitoring the processes may be provided by analog and/or digital input connections of system controller 250 from various process tool sensors. The signals for controlling the processes may be output on the analog and/or digital output connections of process tool 200. Non-limiting examples of process tool sensors that may be monitored include mass flow controllers (MFCs), pressure sensors (such as manometers), temperature sensors such as thermocouples, etc. Appropriately programmed feedback and control algorithms may be used with data from these sensors to maintain process conditions.

System controller 250 may provide machine-readable instructions for implementing the above-described deposition processes. The instructions may control a variety of process parameters, such as DC power level, RF bias power level, pressure, temperature, etc. The instructions may control the parameters to perform film deposition operations as described herein.

Thus, the system controller will typically include one or more memory devices and one or more processors configured to execute machine-readable instructions so that the apparatus will perform operations in accordance with the processes disclosed herein. Machine-readable, non-transitory media containing instructions for controlling operations in accordance with the substrate processing operations disclosed herein may be coupled to the system controller.

The various apparatuses and methods described above may be used in conjunction with lithographic patterning tools and/or processes, for example, for the fabrication or manufacture of semiconductor devices, displays, LEDs, photovoltaic panels and the like. Typically, though not necessarily, such tools will be used or processes conducted together and/or contemporaneously in a common fabrication facility.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Lithographic Patterning

Lithographic patterning of a film typically includes some or all of the following operations, each operation enabled with a number of possible tools: (1) application of photoresist on a substrate, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or substrate by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

### Other Embodiments

Although the foregoing disclosed techniques, operations, processes, methods, systems, apparatuses, tools, films, chemistries, and compositions have been described in detail within the context of specific embodiments for the purpose of promoting clarity and understanding, it will be apparent to one of ordinary skill in the art that there are many alternative ways of implementing foregoing embodiments which are within the spirit and scope of this disclosure. Accordingly, the embodiments described herein are to be viewed as illustrative of the disclosed inventive concepts rather than restrictively, and are not to be used as an impermissible basis for unduly limiting the scope of any claims eventually directed to the subject matter of this disclosure.

1. A method of depositing a film of material on a semiconductor substrate in a processing chamber, the method comprising:
(a) flowing a film precursor into a processing chamber through a showerhead while the showerhead is substantially maintained at a first temperature;
(b) adsorbing the film precursor onto a substrate held on a substrate holder in the processing chamber such that the precursor forms an adsorption-limited layer on the substrate while the substrate holder is substantially maintained at a second temperature;
(c) removing at least some unadsorbed film precursor from the volume surrounding the adsorbed film precursor; and
(d) reacting adsorbed film precursor, after removing unadsorbed film precursor in (c), to form a film layer on the substrate;
wherein the first temperature is at least 10° C. above the second temperature.

2. The method of claim 1, further comprising:
(e) removing desorbed film precursor and/or reaction by-product from the volume surrounding the film layer when present after reacting the adsorbed film precursor.

3. The method of claim 2, further comprising repeating (a)-(e) one or more times to deposit additional layer(s) of film on the substrate.

4. The method of claim 1, wherein the second temperature is between about 45 and 55° C.

5. The method of claim 1, wherein the first temperature is between about 10 and 20° C. above the second temperature.

6. The method of claim 1, wherein the first temperature is between about 15 and 25° C. above the second temperature.

7. The method of claim 1, wherein the temperature of the showerhead varies by less than about 2° C. from the first temperature during (a)-(d).

8. The method of claim 1, wherein the temperature of the showerhead varies by less than about 1° C. from the first temperature during (a)-(d).

9. The method of claim 1, wherein the temperature of the substrate varies by less than about 2° C. from the second temperature during (a)-(d).

10. The method of claim 1, wherein the temperature of the substrate varies by less than about 1° C. from the second temperature during (a)-(d).

11. The method of claim 1, wherein the substrate holder is substantially maintained at the second temperature by actively cooling the substrate holder.

12. The method of claim 11, wherein the substrate holder is a pedestal, and the pedestal is actively cooled by flowing a fluid through conduits in the pedestal.

13. The method of claim 1, wherein the showerhead is substantially maintained at the first temperature by heating the showerhead.

14. The method of claim 13, wherein the showerhead is heated by running a current through an electrically resistive element embedded in the showerhead.

15. An apparatus for depositing films of material on semiconductor substrates, the apparatus comprising:
a processing chamber;
a substrate holder in the processing chamber;
a showerhead for flowing film precursor into the processing chamber;
a vacuum source for removing unadsorbed film precursor from the volume surrounding the substrate in the processing chamber;
one or more controller(s) comprising machine-readable instructions for operating the showerhead and vacuum source to deposit films of material onto the substrates, including instructions for:
(a) flowing a film precursor into the processing chamber through the showerhead while substantially maintaining the showerhead at a first temperature;
(b) controlling conditions within the processing chamber such that the film precursor is adsorbed onto a substrate held on a substrate holder in the processing chamber forming an adsorption-limited layer on the substrate while substantially maintaining the substrate holder at a second temperature, the second temperature being at least 10° C. below the first temperature;
(d) removing at least some unadsorbed film precursor from the volume surrounding the adsorbed film precursor; and
(e) reacting adsorbed film precursor, after removing unadsorbed film precursor in (d), to form a film layer on the substrate.

16. The apparatus of claim 15, wherein the showerhead comprises an electrically resistive element for heating the showerhead, and the substrate holder is a pedestal comprising internal cooling conduits.

17. The apparatus of claim 15, wherein the showerhead comprises an electrically resistive element for heating the showerhead and a temperature sensor, and the instructions of the one or more controller(s) further comprise instructions for controlling current flow through the electrically resistive element in response to signals from the temperature sensor.

18. The apparatus of claim 15, wherein the substrate holder is a pedestal comprising internal cooling conduits and a temperature sensor, and the instructions of the one or more controller(s) further comprise instructions for controlling flow of fluid through the cooling conduits in response to signals from the temperature sensor.

19. The apparatus of claim 18, wherein the pedestal substrate holder further comprises an internal electrically resistive element, and the instructions of the one or more controller(s) further comprise instructions for controlling current flow through the electrically resistive element in response to signals from the temperature sensor.

20. A method of depositing a film of material on a semiconductor substrate in a processing chamber, the method comprising:
(a) flowing a film precursor into a processing chamber through a showerhead while the showerhead is substantially maintained at a first temperature;
(b) adsorbing the film precursor onto a substrate held on a substrate holder in the processing chamber, such that the film precursor forms an adsorption-limited layer on the substrate while the substrate holder is substantially maintained at a second temperature;
(c) removing at least some unadsorbed film precursor from the volume surrounding the adsorbed film precursor; and
(d) reacting adsorbed film precursor, after removing unadsorbed film precursor in (d), to form a film layer on the substrate;
wherein the first temperature is at or below the second temperature.
